(19) United States
(12) Patent Application Publication
(10) Pub. No.: US 2020/0393757 A1
(43) Pub. Date: Dec. 17, 2020

(54) PHOTOSENSITIVE COMPOSITION, FILM, METHOD FOR FORMING PATTERN, COLOR FILTER, SOLID-STATE IMAGING ELEMENT, AND IMAGE DISPLAY DEVICE

(71) Applicant: FUJIFILM Corporation, Tokyo (JP)

(72) Inventors: Kazuto Shimada, Haibara-gun (JP); Naotsugu Muro, Haibara-gun (JP)

(73) Assignee: FUJIFILM Corporation, Tokyo (JP)

(21) Appl. No.: 17/003,603

(22) Filed: Aug. 26, 2020

Related U.S. Application Data
(63) Continuation of application No. PCT/JP2019/010520, filed on Mar. 14, 2019.

(30) Foreign Application Priority Data
Mar. 20, 2018 (JP) 2018-052783
Feb. 14, 2019 (JP) 2019-024215

(51) Int. Cl. G03F 7/004; G03F 7/00; G03F 7/038; G02B 1/04

(52) U.S. Cl. CPC G03F 7/0045; G03F 7/0007; G02B 5/208; G02B 1/04; G03F 7/038

(57) ABSTRACT

Provided are a photosensitive composition used for forming a negative tone pattern by development with a developer including an organic solvent, the photosensitive composition including a coloring material, a resin having solubility which decreases in the organic solvent due to an action of acid, and a photoacid generator; a film formed of the photosensitive composition; a method of forming a pattern; a color filter; a solid-state imaging element; and an image display device.

### CROSS-REFERENCE TO RELATED APPLICATIONS

This application is a Continuation of PCT International Application No. PCT/JP2019/010520 filed on Mar. 14, 2019, which claims priority under 35 U.S.C § 119(a) to Japanese Patent Application No. 2018-052783 filed on Mar. 20, 2018 and Japanese Patent Application No. 2019-024215 filed on Feb. 14, 2019. Each of the above application(s) is hereby expressly incorporated by reference, in its entirety, into the present application.

### BACKGROUND OF THE INVENTION

### 1. Field of the Invention

The present invention relates to a photosensitive composition. More specifically, the present invention relates to a photosensitive composition used for forming a negative tone pattern by development with a developer including an organic solvent. The present invention further relates to a film formed of the photosensitive composition, a method for forming a pattern, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

A film including a coloring material, such as a color filter, has been produced by a pattern formation by performing exposure and development, for example, using a photosensitive composition including a coloring material (refer to JP2017-126044A and JP2011-039319A).

### SUMMARY OF THE INVENTION

The photosensitive composition used for producing the film including a coloring material, such as a color filter, may be used after being stored for a long time. In addition, the photosensitive composition may be stored under a low-temperature environment of, for example, 5° C. or lower.

In addition, regarding the film including a coloring material, such as a color filter, it is desired that the pattern to be formed has good rectangularity and a light leak (crosstalk) to other adjacent films is small.

Therefore, an object of the present invention is to provide a photosensitive composition capable of forming a pattern which has good rectangularity and has suppressed the light leak to other adjacent films even in a case where the photosensitive composition is stored for a long time. Another object of the present invention is to provide a film, a method for forming a pattern, a color filter, a solid-state imaging element, and an image display device.

According to the studies conducted by the present inventors, it has been found that the above-described object can be achieved by adopting the following configuration, thereby leading to the completion of the present invention. Therefore, the present invention provides the following.

<1> A photosensitive composition used for forming a negative tone pattern by development with a developer including an organic solvent, the photosensitive composition comprising:

a coloring material;

a resin having solubility which decreases in the organic solvent due to an action of acid; and

a photoacid generator.

<2> The photosensitive composition according to <1>,

in which a content of the coloring material in a total solid content of the photosensitive composition is 55% by mass or more.

<3> The photosensitive composition according to <1> or <2>,

in which a content of the resin having solubility which decreases in the organic solvent due to an action of acid, in a total amount of resins included in the photosensitive composition is 40% by mass or more.

<4> The photosensitive composition according to any one of <1> to <3>,

in which a content of the resin having solubility which decreases in the organic solvent due to an action of acid, in a total solid content of the photosensitive composition is 10% to 60% by mass.

<5> The photosensitive composition according to any one of <1> to <4>,

in which the resin having solubility which decreases in the organic solvent due to an action of acid, includes a group decomposed by the action of acid to generate a polar group.

<6> The photosensitive composition according to any one of <1> to <5>,

in which the resin having solubility which decreases in the organic solvent due to an action of acid, has a structure in which a polar group is protected by a group to be decomposed and to be eliminated by the action of acid.

<7> The photosensitive composition according to <6>,

in which the group to be decomposed and to be eliminated by the action of acid is a group represented by any one of Formulae (Y1) to (Y4),

—C(R³¹)(R³²)(R³³) Formula (Y1):

—C(═O)OC(R³¹)(R³²)(R³³) Formula (Y2):

—C(R³⁶)(R³⁷)(OR³⁸) Formula (Y3):

—C(Rn)(H)(Ar) Formula (Y4):

in Formulae (Y1) and (Y2), R³¹ to R³³ each independently represent an alkyl group, and two of R³¹ to R³³ may be bonded to each other to form a ring,

in Formula (Y3), R³⁶ and R³⁷ each independently represent a hydrogen atom, an alkyl group, or an aryl group, in which at least one of R³⁶ or R³⁷ is an alkyl group or an aryl group, R³⁸ represents an alkyl group or an aryl group, and R³⁶ or R³⁷, and R³⁸ may be bonded to each other to form a ring, and

in Formula (Y4), Ar represents an aromatic ring group, Rn represents an alkyl group or an aryl group, and Rn and Ar may be bonded to each other to form a ring.

<8> The photosensitive composition according to <6> or <7>,

in which a formula weight of the group to be decomposed and to be eliminated by the action of acid is 170 or less.

<9> The photosensitive composition according to any one of <1> to <8>, further comprising:

an acid crosslinking agent.

<10> The photosensitive composition according to any one of <1> to <9>,

in which a content of a photoradical polymerization initiator in a total solid content of the photosensitive composition is 4% by mass or less.

<11> The photosensitive composition according to any one of <1> to <10>,

in which a content of a radical polymerizable monomer in a total solid content of the photosensitive composition is 5% by mass or less.

<12> A film obtained from the photosensitive composition according to any one of <1> to <11>.

<13> A method for forming a pattern, the method comprising:

a step of forming a photosensitive composition layer on a support using the photosensitive composition according to any one of <1> to <11>;

a step of irradiating the photosensitive composition layer with light to patternwise expose the photosensitive composition layer; and

a step of removing and developing the photosensitive composition layer of an unexposed area using a developer including an organic solvent.

<14> A method for producing a color filter, the method comprising:

after forming a first pixel using the method for forming a pattern according to <13>, forming a second pixel on an area in which the first pixel using the method for forming a pattern according to <13> is removed.

<15> A color filter comprising:

the film according to <12>.

<16> A solid-state imaging element comprising:

the film according to <12>.

<17> An image display device comprising:

the film according to <12>.

According to the present invention, it is possible to provide a photosensitive composition capable of forming a pattern which has good rectangularity and has suppressed the light leak to other adjacent films even in a case where the photosensitive composition is stored for a long time. It is also possible to provide a film formed of the photosensitive composition, a method for forming a pattern, a color filter, a solid-state imaging element, and an image display device.

### DESCRIPTION OF THE PREFERRED EMBODIMENTS

Hereinafter, the contents of the present invention will be described in detail.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless otherwise specified, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, the weight-average molecular weight (Mw), number-average molecular weight (Mn), and dispersity (also referred to as molecular weight distribution) (Mw/Mn) of a resin are defined as a value in terms of polystyrene according to a gel permeation chromatography (GPC) measurement (solvent: tetrahydrofuran, flow amount (sample injection amount): 10 μL, column: TSK gel Multipore HXL-M manufactured by Tosoh Corporation, column temperature: 40° C., flow rate: 1.0 mL/min, detector: refractive index detector) using a GPC device (HLC-8120GPC manufactured by Tosoh Corporation).

In the present specification, the total solid content refers to a total mass of components other than a solvent from all the components of a composition.

In the present specification, the term “step” is not only an independent step, but also includes a step which is not clearly distinguished from other steps in a case where an intended action of the step is achieved.

<Photosensitive Composition>

The photosensitive composition according to an embodiment of the present invention is a photosensitive composition used for forming a negative tone pattern by development with a developer including an organic solvent, the photosensitive composition comprising a coloring material, a resin having solubility which decreases in the organic solvent due to an action of acid, and a photoacid generator.

According to the present invention, it is possible to provide a photosensitive composition capable of forming a pattern which has good rectangularity and has suppressed the light leak to other adjacent films even in a case where the photosensitive composition is stored for a long time. That is, in the photosensitive composition according to the embodiment of the present invention, in a case of, for example, applying the photosensitive composition on a support to form a photosensitive composition layer and patternwise exposing the photosensitive composition layer, by the action of acid generated from the photoacid generator in an exposed area, it is possible to effectively reduce solubility of the above-described resin in the organic solvent, and it is possible to have a difference in solubility in the organic solvent between the exposed area and an unexposed area. In addition, in a case of developing the exposed photosensitive composition layer using the developer including the organic solvent, the photosensitive composition layer of the unexposed area is removed by the developer, and the exposed area of the photosensitive composition layer remains as a pattern (negative tone pattern). Therefore, it is possible to form a pattern having excellent rectangularity. In addition, in a case where a negative tone pattern is formed using a negative photocurable photosensitive composition in the related art, the thickness of the obtained pattern is not particularly changed after exposure. However, in the case of the photosensitive composition according to the embodiment of the present invention, by subjecting the developed pattern to a heat treatment, a resin included in the developed pattern is decomposed. Therefore, the pattern can be thinner than the pattern immediately after exposure, and a thinner pattern can be formed. For example, in a case where the resin having solubility which decreases in the organic solvent due to the action of acid, is a resin having a structure in which the polar group described later is protected by a group (leaving group) decomposed and eliminated by the action of acid, the leaving group remaining in the resin included in the exposed pattern is decomposed and removed by the heat treatment after development. Therefore, the pattern can be thinner than the pattern immediately after exposure. A light leak or the like are easier to be suppressed as the obtained pattern is thinner. Therefore, according to the present invention, it is possible to form a pattern having suppressed the light leak to other adjacent films. In addition, according to the photosensitive composition according to the embodiment of the present invention, it is possible to form a pattern which has good rectangularity and has suppressed the light leak to other adjacent films even in a case where the photosensitive composition is stored for a long time. The reason why such an effect can be obtained is assumed that the resin having solubility which decreases in the organic solvent due to the action of acid, and the photoacid generator in the composition are easily compatible with each other in a case of storage.

The photosensitive composition according to the embodiment of the present invention can be preferably used as a composition for forming a color pixel, a light-shielding film, a pixel of an infrared transmission filter layer, and the like. Examples of the color pixel include a pixel having a hue selected from red, blue, green, cyan, magenta, and yellow. Examples of the pixel of an infrared transmission filter layer include a pixel of a filter layer, which satisfies spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). In addition, the pixel of an infrared transmission filter layer is also preferably a pixel of a filter layer, which satisfies any one of the following spectral characteristics (1) to (4).

(1): pixel of a filter layer in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 80% or more).

(2): pixel of a filter layer in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): pixel of a filter layer in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): pixel of a filter layer in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

In a case where the photosensitive composition according to the embodiment of the present invention is used as a composition for forming the pixel of an infrared transmission filter layer, the photosensitive composition according to the embodiment of the present invention preferably satisfies spectral characteristics that Amin/Bmax, which is a ratio of the minimum value Amin of an absorbance in a wavelength range of 400 to 640 nm to the maximum value Bmax of an absorbance in a wavelength range of 1100 to 1300 nm, is 5 or more. Amin/Bmax is more preferably 7.5 or more, still more preferably 15 or more, and particularly preferably 30 or more.

An absorbance Aλ at a wavelength κ is defined by the following equation (1).

Aκ=−log(Tλ/100) (1)

Aλ is an absorbance at the wavelength κ and n is a transmittance (%) at the wavelength λ.

In the present invention, the value of the absorbance may be a value measured in the form of a solution, or may be a value measured in the form of a film formed using a photosensitive composition. In a case of measuring the absorbance in the form of a film, it is preferable that the value is measured by using a film formed using a method including: applying a photosensitive composition to a glass substrate using a method such as spin coating such that a thickness of the film after drying is a predetermined thickness; and drying the photosensitive composition using a hot plate at 100° C. for 120 seconds.

In a case where the photosensitive composition according to the embodiment of the present invention is used as a composition for forming the pixel of an infrared transmission filter layer, the photosensitive composition according to the embodiment of the present invention more preferably satisfies any one of the following spectral characteristics (11) to (14).

(11): Amin1/Bmax1, which is a ratio of the minimum value Amin1 of an absorbance in a wavelength range of 400 to 640 nm to the maximum value Bmax1 of an absorbance in a wavelength range of 800 to 1300 nm, is 5 or more, preferably 7.5 or more, more preferably 15 or more, and still more preferably 30 or more. According to this aspect, it is possible to form a film capable of shielding light in a wavelength range of 400 to 640 nm and transmitting light having a wavelength of 720 nm or more.

(12): Amin2/Bmax2, which is a ratio of the minimum value Amin2 of an absorbance in a wavelength range of 400 to 750 nm to the maximum value Bmax2 of an absorbance in a wavelength range of 900 to 1300 nm, is 5 or more, preferably 7.5 or more, more preferably 15 or more, and still more preferably 30 or more. According to this aspect, it is possible to form a film capable of shielding light in a wavelength range of 400 to 750 nm and transmitting light having a wavelength of 850 nm or more.

(13): Amin3/Bmax3, which is a ratio of the minimum value Amin3 of an absorbance in a wavelength range of 400 to 850 nm to the maximum value Bmax3 of an absorbance in a wavelength range of 1000 to 1300 nm, is 5 or more, preferably 7.5 or more, more preferably 15 or more, and still more preferably 30 or more. According to this aspect, it is possible to form a film capable of shielding light in a wavelength range of 400 to 850 nm and transmitting light having a wavelength of 940 nm or more.

(14): Amin4/Bmax4, which is a ratio of the minimum value Amin4 of an absorbance in a wavelength range of 400 to 950 nm to the maximum value Bmax4 of an absorbance in a wavelength range of 1100 to 1300 nm, is 5 or more, preferably 7.5 or more, more preferably 15 or more, and still more preferably 30 or more. According to this aspect, it is possible to form a film capable of shielding light in a wavelength range of 400 to 950 nm and transmitting light having a wavelength of 1040 nm or more.

The photosensitive composition according to the embodiment of the present invention can be preferably used as a photosensitive composition for a solid-state imaging element. In addition, the photosensitive composition according to the embodiment of the present invention can be preferably used as a photosensitive composition for a color filter. Specifically, the photosensitive composition according to the embodiment of the present invention can be preferably used as a photosensitive composition for forming a pixel of a color filter, and can be more preferably used as a photosensitive composition for forming a pixel of a color filter used in a solid-state imaging element.

Hereinafter, the respective components used in the photosensitive composition according to the embodiment of the present invention will be described.

<<Coloring Material>>

The photosensitive composition according to the embodiment of the present invention includes a coloring material. Examples of the coloring material include a chromatic colorant, a black colorant, and an infrared absorbing coloring material. The coloring material may be a pigment or a dye. The average primary particle diameter of the pigment is preferably 0.01 to 0.1 μm and more preferably 0.01 to 0.05 The average primary particle diameter of the pigment can be measured using a transmission electron microscope. As the transmission electron microscope, for example, a transmission microscope HT7700 manufactured by Hitachi High-Tech Corporation. can be used. A maximum length (Dmax: maximum length between two points on a contour of a particle image) and a maximum perpendicular length (DV-max: shortest length connecting perpendicularly between two straight lines in a case where the image is interposed between the two straight lines parallel with the maximum length) of a particle image obtained by using a transmission electron microscope are measured, and the geometric mean value (Dmax×DV-max)^{1/2} thereof is defined as a particle diameter. By measuring particle diameters of 100 or more particles by the method, the arithmetic average value thereof is defined as the average primary particle diameter of the pigment. The “average primary particle diameter” in Examples of the present specification is also the same as the above-described arithmetic average value. In a case where a pigment is used as the coloring material, so-called environmental resistance such as heat resistance and light resistance can be further improved with regard to the obtained film. In addition, in a case where a dye is used as the coloring material, a film having a clearer hue is easily formed, for example, a film having excellent color separation from other pixels is easily formed.

In the present specification, the coloring material is preferably a component different from a pigment derivative. That is, in the present specification, it is preferable that the coloring material does not include a pigment derivative.

(Chromatic Colorant)

Examples of the chromatic colorant include red colorants, green colorants, blue colorants, yellow colorants, violet colorants, and orange colorants. The chromatic colorant may be a pigment or a dye.

The pigment used as the chromatic colorant is preferably an organic pigment. Examples of the organic pigment include the following pigments:

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C. I. Pigment Green 7, 10, 36, 37, 58, 59, 62, and 63 (all of which are green pigments);

C. I. Pigment Violet 1, 19, 23, 27, 32, 37, and 42 (all of which are violet pigments); and

C. I. Pigment Blue 1, 2, 15, 15:1, 15:2, 15:3, 15:4, 15:6, 16, 22, 60, 64, 66, 79, and 80 (all of which are blue pigments).

Among these organic pigments, one kind thereof may be used alone, or two or more kinds thereof may be used in combination.

In addition, as the yellow pigment, a metal azo pigment which includes at least one kind of an anion selected from an azo compound represented by Formula (I) or an azo compound having a tautomeric structure of the azo compound represented by Formula (I), two or more kinds of metal ions, and a melamine compound can be used.

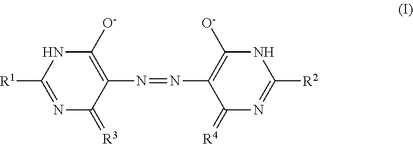

In the formula, R¹ and R² each independently represent —OH or —NR⁵R⁶, R³ and R⁴ each independently represent ═O or ═NR⁷, and R⁵ to R⁷ each independently represent a hydrogen atom or an alkyl group. The alkyl group represented by R⁵ to R⁷ preferably has 1 to 10 carbon atoms, more preferably has 1 to 6 carbon atoms, and still more preferably has 1 to 4 carbon atoms. The alkyl group may be any of linear, branched, and cyclic forms, and is preferably linear or branched and more preferably linear. The alkyl group may have a substituent. The substituent is preferably a halogen atom, a hydroxy group, an alkoxy group, a cyano group, or an amino group.

In Formula (I), it is preferable that R¹ and R² are —OH. In addition, it is preferable that R³ and R⁴ are ═O.

It is preferable that the melamine compound in the metal azo pigment is a compound represented by Formula (II).

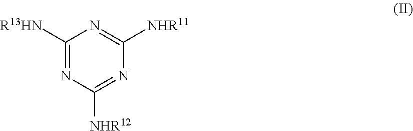

In the formula, R¹¹ to R¹³ each independently represent a hydrogen atom or an alkyl group. The alkyl group preferably has 1 to 10 carbon atoms, more preferably has 1 to 6 carbon atoms, and still more preferably has 1 to 4 carbon atoms. The alkyl group may be any of linear, branched, and cyclic forms, and is preferably linear or branched and more preferably linear. The alkyl group may have a substituent. The substituent is preferably a hydroxy group. It is preferable that at least one of R¹¹ to R¹³ is a hydrogen atom, and it is more preferable that all of R¹¹ to R¹³ are hydrogen atoms.

It is preferable that the metal azo pigment is a metal azo pigment according to an aspect including the at least one kind of an anion selected from an azo compound represented by Formula (I) or an azo compound having a tautomeric structure of the azo compound represented by Formula (I), metal ions including at least Zn²⁺ and Cu²⁺, and a melamine compound. In this aspect, Zn²⁺ and Cu²⁺ are contained preferably in the total amount of 95% to 100% by mole, more preferably 98% to 100% by mole, still more preferably 99.9% to 100% by mole, and particularly preferably 100% with respect to 1 mol of all the metal ions of the metal azo pigment. In addition, a molar ratio of Zn²⁺ to Cu²⁺ in the metal azo pigment is preferably Zn²⁺:Cu²⁺=199:1 to 1:15, more preferably 19:1 to 1:1, and still more preferably 9:1 to 2:1. In addition, in this aspect, the metal azo pigment may further include a divalent or trivalent metal ion (hereinafter, also referred to as a metal ion Me1) in addition to Zn²⁺ and Cu²⁺. Examples of the metal ion Me1 include Ni²⁺, Al³⁺, Fe²⁺, Fe³⁺, Co²⁺, Co³⁺, La³⁺, Ce³⁺, Pr³⁺, Nd²⁺, Nd³⁺, Sm²⁺, Sm³⁺, Eu²⁺, Eu³⁺, Gd³⁺, Tb³⁺, Dy³⁺, Ho³⁺, Yb²⁺, Yb³⁺, Er³⁺, Tm³⁺, Mg²⁺, Ca²⁺, Sr³⁺, Mn²⁺, Y³⁺, Se³⁺, Ti²⁺, Ti³⁺, Nb³⁺, Mo²⁺, Mo³⁺, V²⁺, V³⁺, Zr²⁺, Zr³⁺, Cd²⁺, Cr³⁺, Pb², and Ba²⁺. Among these, at least one selected from Al³⁺, Fe²⁺, Fe³⁺, Co²⁺, Co³⁺, La³⁺, Ce³⁺, Pr³⁺, Nd³⁺, Sm³⁺, Eu³⁺, Gd³⁺, Tb³⁺, Dy³⁺, Ho³⁺, Yb³⁺, Er³⁺, Tm³⁺, Mg²⁺, Ca²⁺, Sr²⁺, Mn²⁺, and Y³⁺ is preferable, at least one selected from Al³⁺, Fe²⁺, Fe³⁺, Co²⁺, Co³⁺, La³⁺, Ce³⁺, Pr³⁺, Nd³⁺, Sm³⁺, Tb³⁺, Ho³⁺, and Sr²⁺ is still more preferable, and at least one selected from Al³⁺, Fe²⁺, Fe³⁺, Co²⁺, or Co³⁺ is particularly preferable. The content of the metal ion Me1 is preferably 5% by mole or less, more preferably 2% by mole or less, and still more preferably 0.1% by mole or less based on 1 mol of all the metal ions of the metal azo pigment.

With regard to details of the metal azo pigment, reference can be made to the description in paragraph Nos. 0011 to 0062 and 0137 to 0276 of JP2017-171912A, paragraph Nos. 0010 to 0062 and 0138 to 0295 of JP2017-171913A, paragraph Nos. 0011 to 0062 and 0139 to 0190 of JP2017-171914A, and paragraph Nos. 0010 to 0065 and 0142 to 0222 of JP2017-171915A, the contents of which are incorporated herein by reference.

In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

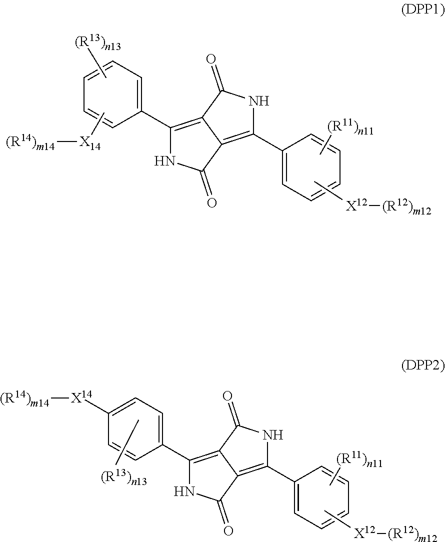

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Preferred specific examples of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A.

In addition, an aluminum phthalocyanine compound having a phosphorus atom can also be used as the blue pigment. Specific examples thereof include the compounds described in paragraphs 0022 to 0030 of JP2012-247591A and paragraph 0047 of JP2011-157478A.

The dye is not particularly limited and a known dye can be used. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethane-based dye. In addition, a multimer of these dyes may be used. In addition, dyes described in JP2015-028144A and JP2015-034966A can also be used.

(Black Colorant)

Examples of the black colorant include an inorganic black colorant and an organic black colorant.

It is preferable that the inorganic black colorant is a pigment (inorganic black pigment). The inorganic black pigment is not particularly limited, and a known inorganic black pigment can be used. Examples thereof include carbon black, titanium black, and graphite, and carbon black or titanium black is preferable and titanium black is more preferable. The titanium black is a black particle containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Specific examples of the inorganic black pigment include Color Index (C. I.) Pigment Black 1 and 7.

It is preferable that the titanium black has a small primary particle diameter of the individual particles and has a small average primary particle diameter. Specifically, the average primary particle diameter is preferably in a range of 10 nm to 45 nm.

The specific surface area of the titanium black is not particularly limited, but a value measured by Brunauer, Emmett, Teller (BET) method is preferably 5 m²/g to 150 m²/g and more preferably 20 m²/g to 120 m²/g. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.).

The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference.

Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include the compounds described in JP2010-534726A, JP2012-515233A, JP2012-515234A, and the like, and the bisbenzofuranone compound is available, for example, as “Irgaphor Black” manufactured by BASF. Examples of the perylene compound include C. I. Pigment Black 31 and 32. Examples of the azomethine compound include the compounds described in JP1989-170601A (JP-H01-170601A) and JP1990-034664A (JP-H02-034664A), and the azomethine compound is available, for example, “CHROMOFINE BLACK A1103” manufactured by Dainichiseika Color & Chemicals Mfg. Co., Ltd.

(Infrared Absorbing Coloring Material)

The infrared absorbing coloring material is preferably a compound having a maximum absorption wavelength in a range of 700 to 1300 nm, and more preferably a compound having a maximum absorption wavelength in a range of 700 to 1000 nm. The infrared absorbing coloring material may be a pigment or a dye.

As the infrared absorbing coloring material, at least one selected from a pyrrolopyrrole compound, a cyanine compound, a squarylium compound, a phthalocyanine compound, a naphthalocyanine compound, a quaterrylene compound, a merocyanine compound, a croconium compound, an oxonol compound, a diimmonium compound, a dithiol compound, a triarylmethane compound, a pyrromethene compound, an azomethine compound, an anthraquinone compound, and a dibenzofuranone compound is preferable, at least one selected from a pyrrolopyrrole compound, a cyanine compound, a squarylium compound, a phthalocyanine compound, a naphthalocyanine compound, and a diimmonium compound is more preferable, at least one selected from a pyrrolopyrrole compound, a cyanine compound, and a squarylium compound is still more preferable, and a pyrrolopyrrole compound is particularly preferable.

Examples of the pyrrolopyrrole compound include compounds described in paragraph Nos. 0016 to 0058 of JP2009-263614A, compounds described in paragraph Nos. 0037 to “0052 of JP2011-068731A, and compounds described in paragraph Nos. 0010 to 0033 of WO2015/166873A, the contents of which are incorporated herein by reference.

Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in WO2013/133099A, compounds described in WO2014/088063A, compounds described in JP2014-126642A, compounds described in JP2016-146619A, compounds described in JP2015-176046A, compounds described in JP2017-025311A, compounds described in WO2016/154782A, compounds described in JP5884953B, compounds described in JP6036689B, compounds described in JP5810604B, and compounds described in JP2017-068120A, the contents of which are incorporated herein by reference.

Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, and compounds described in JP2017-031394A, the contents of which are incorporated herein by reference.

Examples of the diimmonium compound include compounds described in JP2008-528706A, the contents of which are incorporated herein by reference. Examples of the phthalocyanine compound include compounds described in paragraph No. 0093 of JP2012-077153A, oxytitaniumphthalocyanine described in JP2006-343631A, and compounds described in paragraph Nos. 0013 to 0029 of JP2013-195480A, the contents of which are incorporated herein by reference. Examples of the naphthalocyanine compound include compounds described in paragraph No. 0093 of JP2012-077153A, the contents of which are incorporated herein by reference.

In the present invention, a tungsten compound or a metal boron compound may be used in the infrared absorbing coloring material. Examples of the tungsten compound include a tungsten oxide-based compound, a tungsten boride-based compound, and a tungsten sulfide-based compound, and a tungsten-oxide based compound represented by the following formula (compositional formula) (II) is preferable.

MₓW_{y}O_{z} (II)

M represents a metal, W represents tungsten, and O represents an oxygen atom.

0.001≤x/y≤1.1

2.2≤z/y≤3.0

Examples of the metal represented by M include an alkali metal, an alkaline earth metal, Mg, Zr, Cr, Mn, Fe, Ru, Co, Rh, Ir, Ni, Pd, Pt, Cu, Ag, Au, Zn, Cd, Al, Ga, In, Tl, Sn, Pb, Ti, Nb, V, Mo, Ta, Re, Be, Hf, Os, and Bi, and alkali metal is preferable, Rb or Cs is more preferable, and Cs is still more preferable. The metal represented by M may be one kind or two or more kinds.

Specific examples of the tungsten-oxide based compound represented by the formula (II) include Cs_{0.33}WO₃, Rb_{0.33}WO₃, K_{0.33}WO₃, and Ba_{0.33}WO₃, and Cs_{0.33}WO₃ or Rb_{0.33}WO₃ is preferable and Cs_{0.33}WO₃ is more preferable.

The tungsten compound is available as a commercially available product. In a case where the tungsten compound is a tungsten-oxide based compound, the tungsten-oxide based compound can be obtained according to a method of subjecting a tungsten compound to a heat treatment under an inert gas atmosphere or a reducing gas atmosphere (refer to JP4096205B). In addition, the tungsten-oxide based compound is available, for example, as a dispersion of tungsten fine particles such as YMF-02 manufactured by SUMITOMO METAL MINING CO., LTD.

Examples of the metal boron compound include lanthanum boride (LaB₆), praseodymium boride (PrB₆), neodymium boride (NdB₆), cerium boride (CeB₆), yttrium boride (YB₆), titanium boride (TiB₂), zirconium boride (ZrB₂), hafnium boride (HfB₂), vanadium boride (VB₂), tantalum boride (TaB₂), chromium boride (CrB and CrB₂), molybdenum boride (MoB₂, Mo₂B₅, and MoB), and tungsten boride (W₂B₅), and lanthanum boride (LaB₆) is preferable. The metal boron compound is available as a commercially available product, for example, as a dispersion of metal boron compound fine particles such as KHF-7 manufactured by SUMITOMO METAL MINING CO., LTD.

The content of the coloring material in the total solid content of the photosensitive composition is preferably 40% by mass or more, more preferably 50% by mass or more, and from the reason that a film with further reduced crosstalk is easily obtained, still more preferably 55% by mass or more and particularly preferably 60% by mass or more. From the viewpoint of film forming properties, the upper limit is preferably 80% by mass or less, more preferably 75% by mass or less, and still more preferably 70% by mass or less. It is preferable that the value of the content of the coloring material is a value not including the content of the pigment derivative.

The coloring material used in the photosensitive composition according to the embodiment of the present invention preferably includes at least one selected from the chromatic colorant and the black colorant. In addition, the content of the chromatic colorant and the black colorant in the total mass of the coloring material is preferably 30% by mass or more, more preferably 50% by mass or more, and still more preferably 70% by mass or more. The upper limit may be 100% by mass, or 90% by mass or less.

In the coloring material used in the photosensitive composition according to the embodiment of the present invention, the content of the pigment in the total mass of the coloring material is preferably 50% by mass or more, more preferably 70% by mass or more, and still more preferably 90% by mass or more.

In a case where the photosensitive composition according to the embodiment of the present invention is used as a composition for forming a color pixel, the content of the chromatic colorant in the total solid content of the photosensitive composition is preferably 40% by mass or more, more preferably 50% by mass or more, still more preferably 55% by mass or more, and particularly preferably 60% by mass or more. In addition, the content of the chromatic colorant in the total mass of the coloring material is preferably 50% by mass or more, more preferably 60% by mass or more, and still more preferably 65% by mass or more. The upper limit may be 100% by mass, or 95% by mass or less. It is preferable that the value of the content of the chromatic colorant is a value not including the content of the pigment derivative.

In a case where the photosensitive composition according to the embodiment of the present invention is used as a composition for forming a light-shielding film, the content of the black colorant (preferably inorganic black colorant and more preferably inorganic black pigment) in the total solid content of the photosensitive composition is preferably 40% by mass or more, more preferably 50% by mass or more, still more preferably 55% by mass or more, and particularly preferably 60% by mass or more. In addition, the content of the black colorant in the total mass of the coloring material is preferably 50% by mass or more, more preferably 70% by mass or more, and still more preferably 80% by mass or more. The upper limit may be 100% by mass, or 95% by mass or less.

In a case where the photosensitive composition according to the embodiment of the present invention is used as a composition for forming the pixel of an infrared transmission filter layer, the coloring material used in the present invention preferably satisfies at least one of the following requirements (1) to (3).
(1): the coloring material includes two or more kinds of chromatic colorants, and a combination of the two or more kinds of chromatic colorants forms black. It is preferable that a combination of two or more kinds of colorants selected from red colorants, blue colorants, yellow colorants, violet colorants, and green colorants forms black.
(2): the coloring material includes an organic black colorant.
(3): in the above (1) or (2), the infrared absorbing coloring material is further included.

Examples of preferred combinations of the aspect (1) include the following.
(1-1): aspect in which the coloring material contains a red colorant and a blue colorant
(1-2): aspect in which the coloring material contains a red colorant, a blue colorant, and a yellow colorant
(1-3): aspect in which the coloring material contains a red colorant, a blue colorant, a yellow colorant, and a violet colorant
(1-4): aspect in which the coloring material contains a red colorant, a blue colorant, a yellow colorant, a violet colorant, and a green colorant
(1-5): aspect in which the coloring material contains a red colorant, a blue colorant, a yellow colorant, and a green colorant
(1-6): aspect in which the coloring material contains a red colorant, a blue colorant, and a green colorant
(1-7): aspect in which the coloring material contains a yellow colorant and a violet colorant

In the aspect (2), it is also preferable to contain a chromatic colorant. By using the organic black colorant and the chromatic colorant in combination, excellent spectral characteristics are easily obtained. Examples of the chromatic colorant used in combination with the organic black colorant include red colorants, blue colorants, and violet colorants, and red colorants or violet colorants are preferable. These colorants may be used alone or in combination of two or more kinds thereof. In addition, the mixing proportion of the chromatic colorant and the organic black colorant is preferably 10 to 200 parts by mass and more preferably 15 to 150 parts by mass of the chromatic colorant with respect to 100 parts by mass of the organic black colorant.

In the aspect (3), the content of the infrared absorbing coloring material in the total mass of the coloring material is preferably 5% to 40% by mass. The upper limit is preferably 30% by mass or less and more preferably 25% by mass or less. The lower limit is preferably 10% by mass or more and more preferably 15% by mass or more.

<<Resin>>

The photosensitive composition according to the embodiment of the present invention contains a resin. The resin is blended in, for example, an application for dispersing a pigment or the like in a composition or an application as a binder. Mainly, a resin which is used for dispersing a pigment or the like is also referred to as a dispersant. However, such applications of the resin are only exemplary, and the resin can also be used for other purposes in addition to such applications.

In the present invention, a resin (hereinafter, also referred to as a resin (A)) having solubility which decreases in the organic solvent due to the action of acid, is contained as the resin. Hereinafter, the resin (A) will be described.

(Resin (A))

As the resin (A), a resin having a group (hereinafter, also referred to as an “acid-decomposable group”) decomposed by the action of acid to generate a polar group is preferable. In addition, it is preferable that the resin (A) has a repeating unit having the acid-decomposable group. The resin (A) can be used as a binder or a dispersant.

As the resin (A), a known resin can be appropriately used. For example, known resins disclosed in paragraph Nos. 0055 to 0191 of US2016/0274458A, paragraph Nos. 0035 to 0085 of US2015/0004544A, and paragraph Nos. 0045 to 0090 of US2016/0147150A can be suitably used as the resin (A).

It is preferable that the acid-decomposable group has a structure in which a polar group is protected by a group (leaving group) decomposed and eliminated by the action of acid.

Examples of the polar group include a carboxyl group, a phenolic hydroxyl group, a fluorinated alcohol group, a sulfo group, a sulfonamide group, a sulfonylimide group, an acidic group (group which dissociates in a 2.38% by mass tetramethylammonium hydroxide aqueous solution) such as an (alkylsulfonyl)(alkylcarbonyl)methylene group, an (alkyl sulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and an alcoholic hydroxyl group.

The alcoholic hydroxyl group is a hydroxyl group bonded to a hydrocarbon group, and is a hydroxyl group other than a hydroxyl group (phenolic hydroxyl group) directly bonded to an aromatic ring, and an aliphatic alcohol group (for example, a hexafluoroisopropanol group) in which an α-position is substituted with an electron-withdrawing group such as a fluorine atom is excluded as the hydroxyl group. As the alcoholic hydroxyl group, a hydroxyl group having a pKa (acid dissociation constant) of 12 to 20 is preferable.

Examples of a preferred polar group include a carboxyl group, a phenolic hydroxyl group, a fluorinated alcohol group (preferably hexafluoroisopropanol group), and a sulfo group.

Examples of the acid-decomposable group include a group in which a hydrogen atom of these groups is substituted with a group (leaving group) decomposed and eliminated by the action of acid. The leaving group is preferably a group represented by any one of Formulae (Y1) to (Y4). Among these, from the reason that the leaving group is easily eliminated in the film at a temperature as low as possible by a heat treatment (baking) after exposure, Formula (Y1) is preferable.

—C(R³¹)(R³²)(R³³) Formula (Y1):

—C(═O)OC(R³¹)(R³²)(R³³) Formula (Y2):

—C(R³⁶)(R³⁷)(OR³⁸) Formula (Y3):

—C(Rn)(H)(Ar) Formula (Y4):

In formulae (Y1) and (Y2), R³¹ to R³³ each independently represent an alkyl group. The alkyl group may be any of linear, branched, and cyclic forms. The alkyl group preferably has 1 to 12 carbon atoms, more preferably has 1 to 6 carbon atoms, and still more preferably 1 to 4 carbon atoms. In a case where all of R³¹ to R³³ are an alkyl group (linear or branched), it is preferable that at least two of R³¹ to R³³ are a methyl group. Among these, R³¹ to R³³ each independently represent preferably a linear or branched alkyl group, and more preferably a linear alkyl group. In Formulae (Y1) and (Y2), two of R³¹ to R³³ may be bonded to each other to form a ring. As the alkyl group represented by R³¹ to R³³, a methyl group, an ethyl group, an n-propyl group, an isopropyl group, an n-butyl group, an isobutyl group, a t-butyl group, a cyclopentyl group, a cyclohexyl group, a norbornyl group, a tetracyclodecanyl group, a tetracyclododecanyl group, or an adamantyl group is preferable.

As the ring formed by bonding two of R³¹ to R³³ to each other, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable, and a monocyclic cycloalkyl group having 5 or 6 carbon atoms is more preferable. In the cycloalkyl group, for example, one of methylene groups constituting the ring may be replaced with a heteroatom such as an oxygen atom or a group having a heteroatom, such as a carbonyl group.

In the group represented by Formula (Y1) or Formula (Y2), for example, an aspect in which R³¹ is a methyl group or an ethyl group and R³² and R³³ are bonded to each other to form the above-described cycloalkyl group is preferable.

In Formula (Y3), R³⁶ and R³⁷ each independently represent a hydrogen atom, an alkyl group, or an aryl group, in which at least one of R³⁶ or R³⁷ is an alkyl group or an aryl group, R³⁸ represents an alkyl group or an aryl group, and R³⁶ or R³⁷, and R³⁸ may be bonded to each other to form a ring. The alkyl group may be any of linear, branched, and cyclic forms. The alkyl group preferably has 1 to 12 carbon atoms, more preferably has 1 to 6 carbon atoms, and still more preferably 1 to 4 carbon atoms. It is preferable that one of R³⁶ and R³⁷ is a hydrogen atom.

Examples of the ring formed by bonding R³⁶ or R³⁷, and R³⁸ to each other include a tetrahydrofuranyl group and a tetrahydropyranyl group.

In Formula (Y4), Ar represents an aromatic ring group and Rn represents an alkyl group or an aryl group. Rn and Ar may be bonded to each other to form a ring. The aromatic ring group represented by Ar is preferably an aryl group.

The formula weight of the leaving group is preferably 170 or less, more preferably 150 or less, and still more preferably 110 or less. The lower limit is preferably 50 or more. In a case where the formula weight of the leaving group is 170 or less, the leaving group is easily decomposed and removed from the resin (A) by the heat treatment after development, or the like even in a case the leaving group remains in the exposed resin (A). Therefore, a thinner film is easily formed.

As the acid-decomposable group, a cumyl ester group, an enol ester group, an acetal ester group, or a tertiary alkyl ester group is preferable, and an acetal group or a tertiary alkyl ester group is more preferable.

As the repeating unit having the acid-decomposable group, the resin (A) preferably has a repeating unit represented by Formula (A1a) or Formula (A1b).

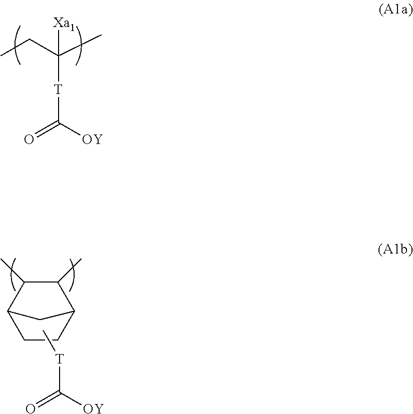

In the formulae, Xa₁ represents a hydrogen atom or an alkyl group. T represents a single bond or a divalent linking group. Y represents an acid-decomposable group.

The alkyl group represented by Xa₁ preferably has 1 to 3 carbon atoms. Xa₁ is preferably a hydrogen atom or a methyl group.

Examples of the divalent linking group represented by T include an alkylene group, a —COO-Rt- group, and a —O-Rt- group. Rt represents an alkylene group having 1 to 5 carbon atoms. T is preferably a single bond or a —COO-Rt- group and more preferably a single bond. Y is preferably any group represented by Formulae (Y1) to (Y4), and more preferably a group represented by Formula (Y1).

As the acid-decomposable group represented by Y is preferably any group represented by Formulae (Y1) to (Y4).

The resin (A) may have only one kind of repeating unit having an acid-decomposable group, or may have two or more kinds thereof.

As the repeating unit having the acid-decomposable group, the resin (A) preferably has a repeating unit represented by Formula (A1a-1) or Formula (A1b-1).

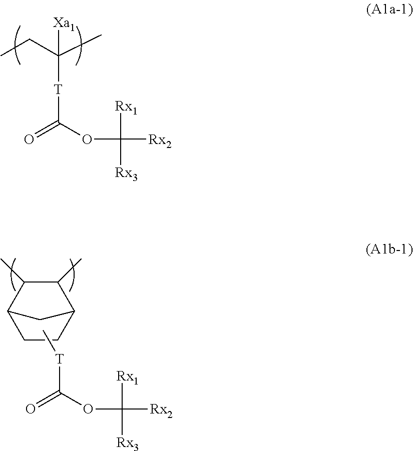

In the formulae, Xa₁ represents a hydrogen atom or an alkyl group. T represents a single bond or a divalent linking group. Rx₁ to Rx₃ each independently represent an alkyl group. Any two of Rx₁ to Rx₃ may be bonded to each other to form a ring structure.

The alkyl group represented by Xa₁ preferably has 1 to 3 carbon atoms. Xa₁ is preferably a hydrogen atom or a methyl group. Examples of the divalent linking group represented by T include an alkylene group, a —COO-Rt- group, and a —O-Rt- group. Rt represents an alkylene group having 1 to 5 carbon atoms. T is preferably a single bond or a —COO-Rt- group and more preferably a single bond.

The alkyl groups of Rx₁, Rx₂, and Rx₃ may be any of linear, branched, and cyclic forms. The alkyl group preferably has 1 to 10 carbon atoms, more preferably has 1 to 5 carbon atoms, and still more preferably has 1 to 3 carbon atoms. In the alkyl groups of Rx₁, Rx₂, and Rx₃, a part of carbon-carbon bonds may be a double bond. In addition, as the cyclic alkyl group, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the ring structure formed by bonding two or Rx₁, Rx₂, and Rx₃ to each other, a monocyclic cycloalkane ring such as a cyclopentyl ring, a cyclohexyl ring, a cycloheptyl ring, and a cyclooctane ring, or a polycyclic cycloalkyl ring such as a norbornane ring, a tetracyclodecane ring, a tetracyclododecane ring, and an adamantane ring is preferable. A cyclopentyl ring, a cyclohexyl ring, or an adamantane ring is more preferable. As the ring structure formed by bonding two or Rx₁, Rx₂, and Rx₃ to each other, the structure shown below is also preferable.

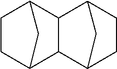 [SMILES: C1CC2CC1C1C3CCC(C3)C21]

Specific examples of the repeating unit represented by Formula (A1a) and the repeating unit represented by Formula (A1b) include repeating units described in paragraph Nos. 0047 to 0067 of JP2017-126044A. In addition, it is preferable that the resin (A) has, as the repeating unit having an acid-decomposable group, a repeating unit described in paragraph Nos. 0336 to 0369 of US2016/0070167A. In addition, the resin (A) may have, as the repeating unit having an acid-decomposable group, a repeating unit including a group decomposed by the action of acid to generate an alcoholic hydroxyl group, the repeating unit being described in paragraph Nos. 0363 and 0364 of US2016/0070167A.

The resin (A) may include only one kind of repeating unit having an acid-decomposable group, or may include two or more kinds thereof in combination. The content (in a case of a plurality of repeating units having an acid-decomposable group, the total thereof) of the repeating unit having an acid-decomposable group, which is included in the resin (A), is preferably 10% to 90% by mole, more preferably 20% to 80% by mole, and still more preferably 30% to 70% by mole with respect to all the repeating units of the resin (A).

The resin (A) preferably has a repeating unit having at least one selected from the group consisting of a lactone structure, a sultone structure, and a carbonate structure.

Any lactone structure or sultone structure may be used as long as the structure has a lactone structure or a sultone structure, but a 5- to 7-membered ring lactone structure or a 5- to 7-membered ring sultone structure is preferable, and a structure in which another ring structure is fused to a 5- to 7-membered ring lactone structure so as to form a bicyclo structure or a spiro structure, or a structure in which another ring structure is fused to a 5- to 7-membered ring sultone structure so as to form a bicyclo structure or a spiro structure is more preferable. It is still more preferable to have a repeating unit having a lactone structure represented by any one of Formulae (LC1-1) to (LC1-21), or having a sultone structure represented by any one of Formulae (SL1-1) to (SL1-3). In addition, the lactone structure or the sultone structure may be directly bonded to the main chain of the repeating unit. Preferred structures are (LC1-1), (LC1-4), (LC1-5), (LC1-8), (LC1-16), (LC1-21) and (SL1-1).

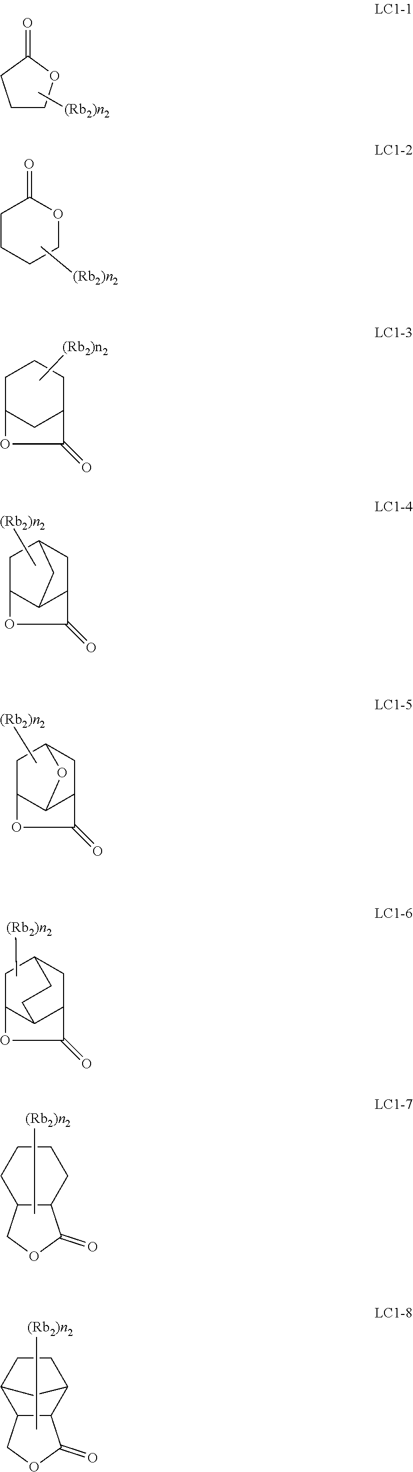

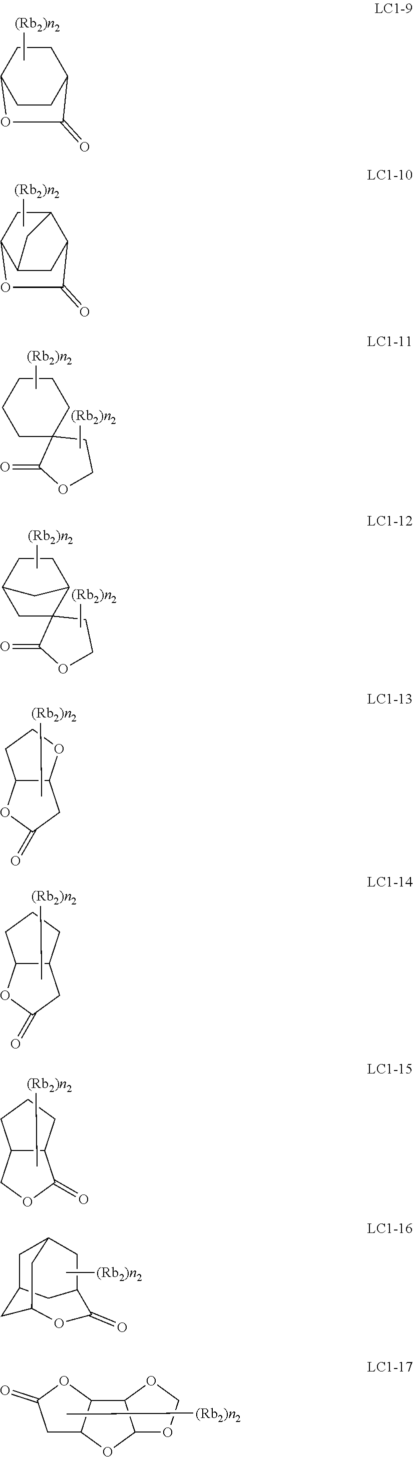

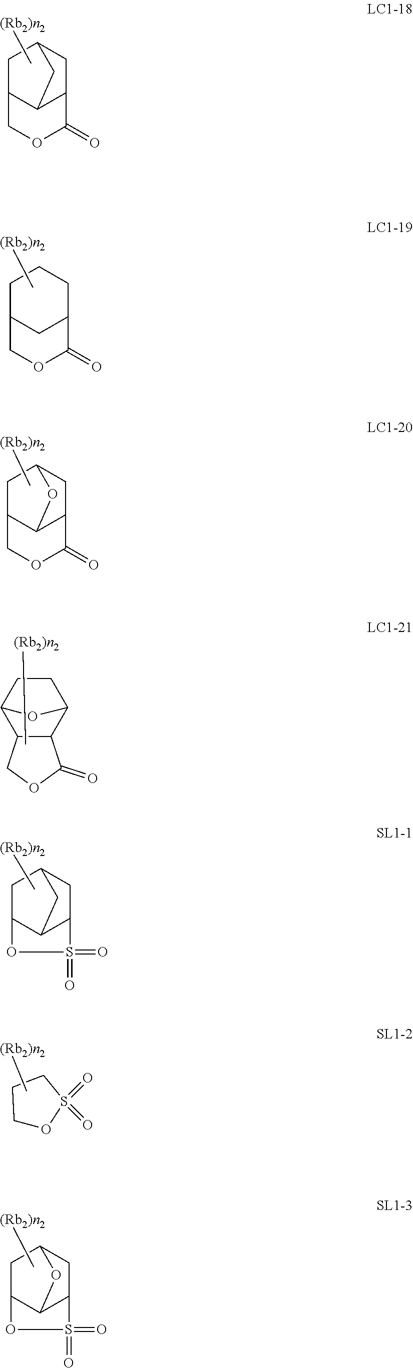

The lactone structure portion or the sultone structure portion may or may not have a substituent (Rb₂). Examples of a preferred substituent (Rb₂) include an alkyl group having 1 to 8 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. An alkyl group having 1 to 4 carbon atoms, a cyano group, or an acid-decomposable group is more preferable. n₂ represents an integer of 0 to 4. In a case where n₂ is 2 or more, a plurality of substituents (Rb₂) may be the same as or different from each other. In addition, a plurality of substituents (Rb₂) may be bonded to each other to form a ring.

The repeating unit having a lactone structure or a sultone structure is preferably a repeating unit represented by Formula (LC).

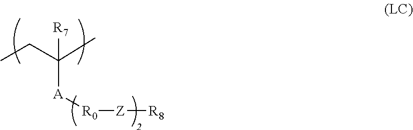

In the formula, A represents an ester bond (group represented by —COO—) or an amide bond (group represented by —CONH—). n is the number of repetitions of a structure represented by —R₀—Z—, represents an integer of 0 to 5, and is preferably 0 or 1 and more preferably 0. In a case where n is 0, —R₀—Z— does not exist, and A and R₈ are bonded by a single bond. R₀ represents an alkylene group, a cycloalkylene group, or a combination thereof. In a case of a plurality of R₀'s, the plurality of R₀'s each independently represent an alkylene group, a cycloalkylene group, or a combination thereof.

Z represents a single bond, an ether bond, an ester bond, an amide bond, a urethane bond, or a urea bond. In a case of a plurality of Z's, the plurality of Z's each independently represent a single bond, an ether bond, an ester bond, an amide bond, a urethane bond, or a urea bond.

R₈ represents a monovalent organic group having the lactone structure or the sultone structure.

R₇ represents a hydrogen atom, a halogen atom, or a monovalent organic group (preferably a methyl group).

The alkylene group or cycloalkylene group of R₀ may have a substituent. Z is preferably an ether bond or an ester bond, and more preferably an ester bond.

Specific examples of the repeating unit having a lactone structure or a sultone structure include repeating units described in paragraph Nos. 0088 to 0091 of JP2017-126044A.

The resin (A) may have a repeating unit having a carbonate structure. The carbonate structure is preferably a cyclic carbonic acid ester structure. A repeating unit having a cyclic carbonic acid ester structure is preferably a repeating unit represented by Formula (A-1).

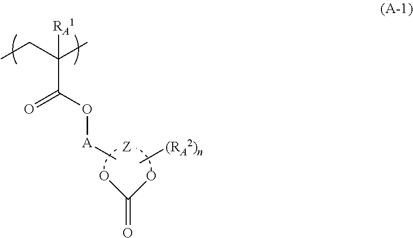

In Formula (A-1), R_{A}¹ represents a hydrogen atom, a halogen atom, or a monovalent organic group (preferably a methyl group). n represents an integer of 0 or more. R_{A}² represents a substituent. In a case where n is 2 or more, R_{A}²'s each independently represent a substituent. A represents a single bond or a divalent linking group. Z represents an atomic group forming a monocyclic structure or a polycyclic structure with the group represented by —O—C(═O)—O— in the formula.

Specific examples of the repeating unit having a carbonate structure include repeating units described in paragraph Nos. 0107 and 0108 of JP2017-126044A.

The resin (A) also preferably has, as the repeating unit having at least one selected from the group consisting of a lactone structure, a sultone structure, and a carbonate structure, repeating units described in paragraph Nos. 0370 to 0414 of US2016/0070167A.

The resin (A) may include only one kind of repeating unit having at least one selected from the group consisting of a lactone structure, a sultone structure, and a carbonate structure, or may include two or more kinds thereof in combination. The content (in a case of a plurality of repeating units having at least one selected from the group consisting of a lactone structure, a sultone structure, and a carbonate structure, the total thereof) of the repeating unit having at least one selected from the group consisting of a lactone structure, a sultone structure, and a carbonate structure, which is included in the resin (A), is preferably 5% to 70% by mole, more preferably 10% to 65% by mole, and still more preferably 20% to 60% by mole with respect to all the repeating units of the resin (A).

The resin (A) can also have a repeating unit having a polar group. Examples of the polar group include the groups described above, and a hydroxyl group, a cyano group, a carboxyl group, or a fluorinated alcohol group is preferable. In addition, the repeating unit having a polar group is preferably a repeating unit having an alicyclic hydrocarbon structure substituted with a polar group. In addition, it is preferable that the repeating unit having a polar group does not have the acid-decomposable group. As an alicyclic hydrocarbon structure in the alicyclic hydrocarbon structure substituted with a polar group, an adamantyl group or a norbornane group is preferable. In addition, specific examples of the repeating unit having a polar group include repeating units disclosed in paragraph Nos. 0415 to 0433 of US2016/0070167A.

The resin (A) may include only one kind of repeating unit having a polar group, or may include two or more kinds thereof in combination. The content of the repeating unit having a polar group is preferably 5% to 40% by mole, more preferably 5% to 30% by mole, and still more preferably 10% to 25% by mole with respect to all the repeating units of the resin (A).

The resin (A) can have a repeating unit having a crosslinkable group. In a case where the resin (A) includes the repeating unit having a crosslinkable group, a film having a high crosslinking density can be formed, and a film excellent in various characteristics such as heat resistance, solvent resistance, and strength is easily formed. Examples of the crosslinkable group include an epoxy group, a methylol group, an alkoxymethylol group, and an acyloxymethyl group, and an epoxy group, an oxetanyl group, a methylol group, or an alkoxymethylol group is preferable, an epoxy group or an oxetanyl group is more preferable, and an epoxy group is still more preferable. With regard to a repeating unit having a crosslinkable group reference can be made to the description in paragraph Nos. 0076 to 0087 of JP2014-238438A, the contents of which are incorporated herein by reference.

The resin (A) may include only one kind of repeating unit having a crosslinkable group, or may include two or more kinds thereof in combination. The content of the repeating unit having a crosslinkable group is preferably 5% to 40% by mole, more preferably 5% to 30% by mole, and still more preferably 10% to 25% by mole with respect to all the repeating units of the resin (A).

Furthermore, the resin (A) can have a repeating unit which does not have any of the acid-decomposable group, the polar group, and the crosslinkable group. The repeating unit which does not have any of the acid-decomposable group, the polar group, and the crosslinkable group is preferably a repeating unit having an alicyclic hydrocarbon structure. Specific examples of the repeating unit which does not have any of the acid-decomposable group, the polar group, and the crosslinkable group include repeating units disclosed in paragraph Nos. 0236 and 0237 of US2016/0026083A, paragraph No. 0433 of US2016/0070167A, and paragraph Nos. 0135 to 0137 of JP2017-126044A.

The resin (A) may include only one kind of repeating unit which does not have any of the acid-decomposable group, the polar group, and the crosslinkable group, or may include two or more kinds thereof in combination. The content of the repeating unit which does not have any of the acid-decomposable group, the polar group, and the crosslinkable group is preferably 5% to 40% by mole, more preferably 5% to 30% by mole, and still more preferably 5% to 25% by mole with respect to all the repeating units of the resin (A).

In the resin (A), it is preferable that all the repeating units are constituted of a (meth)acrylate-based repeating unit. In this case, any of a resin in which all the repeating units are a methacrylate-based repeating unit, a resin in which all the repeating units are an acrylate-based repeating unit, and a resin in which all the repeating units are constituted of a methacrylate-based repeating unit and an acrylate-based repeating unit can be used, but it is preferable to have 50% by mole or less of acrylate-based repeating units with respect to all the repeating units of the resin (A).

The weight-average molecular weight of the resin (A) is preferably 3,000 to 200,000. The lower limit is preferably 6,000 or more, more preferably 8,000 or more, and still more preferably 10,000 or more. The upper limit is preferably 50,000 or less, more preferably 25,000 or less, and still more preferably 15,000 or less. The dispersity (Mw/Mn) is preferably 1.0 to 3.0, more preferably 1.0 to 2.6, still more preferably 1.0 to 2.0, and particularly preferably 1.1 to 2.0.

(Resin (B))

The photosensitive composition according to the embodiment of the present invention can contain, as the resin, a resin (hereinafter, also referred to as a resin (B)) other than the above-described resin (A).

Examples of the resin (B) include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. From the viewpoint of improving heat resistance, as the cyclic olefin resin, a norbornene resin can be preferably used. Examples of a commercially available product of the norbornene resin include ARTON series (for example, ARTON F4520) manufactured by JSR Corporation. In addition, as the resin, resins described in Examples of WO2016/088645A can be used.

In the present invention, a resin having an acid group can be used as the resin (B). Examples of the acid group include a carboxyl group, a phosphoric acid group, a sulfo group, and a phenolic hydroxyl group, and a carboxyl group is preferable. With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. A commercially available product can also be used as the resin having an acid group. Examples of the commercially available product include ACRYBASE FF-426 (manufactured by Fujikura Kasei Co., Ltd.). The acid value of the resin having an acid group is preferably 30 to 200 mgKOH/g. The lower limit is preferably 50 mgKOH/g or more and more preferably 70 mgKOH/g or more. The upper limit is preferably 150 mgKOH/g or less and more preferably 120 mgKOH/g or less.

The resin (B) may have a polymerizable group. Examples of the polymerizable group include an allyl group, a methallyl group, and a (meth)acryloyl group. Examples of a commercially available product of the resin having a polymerizable group include Dianal NR Series (manufactured by Mitsubishi Rayon Co., Ltd.), Photomer 6173 (polyurethane acrylate oligomer containing carboxyl group, manufactured by Diamond Shamrock Corp.), Viscoat R-264 and KS Resist 106 (both of which are manufactured by Osaka Organic Chemical Industry Ltd.), Cyclomer P series (for example, ACA230AA) and Placcel CF 200 series (all of which are manufactured by Daicel Corporation), Ebecryl 3800 (manufactured by Daicel UCB Company, Ltd.), and Acrycure RD-F8 (manufactured by Nippon Shokubai Co., Ltd.).

As the resin (B), a polymer which includes a repeating unit derived from a monomer component including a compound represented by Formula (ED1) and/or a compound represented by Formula (ED2) (hereinafter, these compounds will also be referred to as an “ether dimer”) is also preferable.

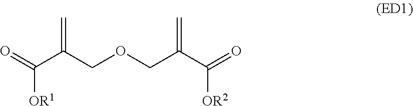

In Formula (ED1), R¹ and R² each independently represent a hydrogen atom or a hydrocarbon group having 1 to 25 carbon atoms, which may have a substituent.

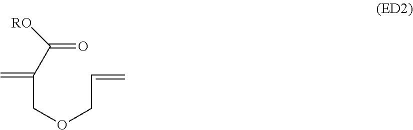

In Formula (ED2), R represents a hydrogen atom or an organic group having 1 to 30 carbon atoms. With regard to the specific examples of Formula (ED2), reference can be made to JP2010-168539A.

With regard to the specific examples of the ether dimer, reference can be made to paragraph No. 0317 of JP2013-029760A, the contents of which are incorporated herein by reference. The ether dimers may be used singly or in combination of two or more kinds thereof.

The resin (B) may include a repeating unit derived from a compound represented by Formula (X).

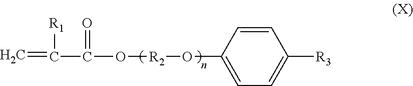

In Formula (X), R¹ represents a hydrogen atom or a methyl group, R² represents an alkylene group having 2 to 10 carbon atoms, and R³ represents a hydrogen atom or an alkyl group having 1 to 20 carbon atoms, which may include a benzene ring. n represents an integer of 1 to 15.

The photosensitive composition according to the embodiment of the present invention can also include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70% by mole or more in a case where the total amount of the acid group and the basic group is denoted by 100% by mole, and more preferably a resin substantially consisting of only an acid group. The acid group included in the acidic dispersant (acidic resin) is preferably a carboxyl group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50% by mole in a case where the total amount of the acid group and the basic group is denoted by 100% by mole. The basic group included in the basic dispersant is preferably an amino group.

It is preferable that the resin used as a dispersant is a graft copolymer. Since the graft copolymer has affinity to a solvent due to the graft chain, the pigment dispersibility and the dispersion stability over time are excellent. Specific examples of the graft copolymer include resins having the following structures. In addition, with regard to details of the graft copolymer, reference can be made to the description in paragraph Nos. 0025 to 0094 of JP2012-255128A, the contents of which are incorporated herein by reference. In addition, examples of the graft copolymer include resins described in paragraph Nos 0072 to 0094 of JP2012-255128A, the contents of which are incorporated herein by reference.

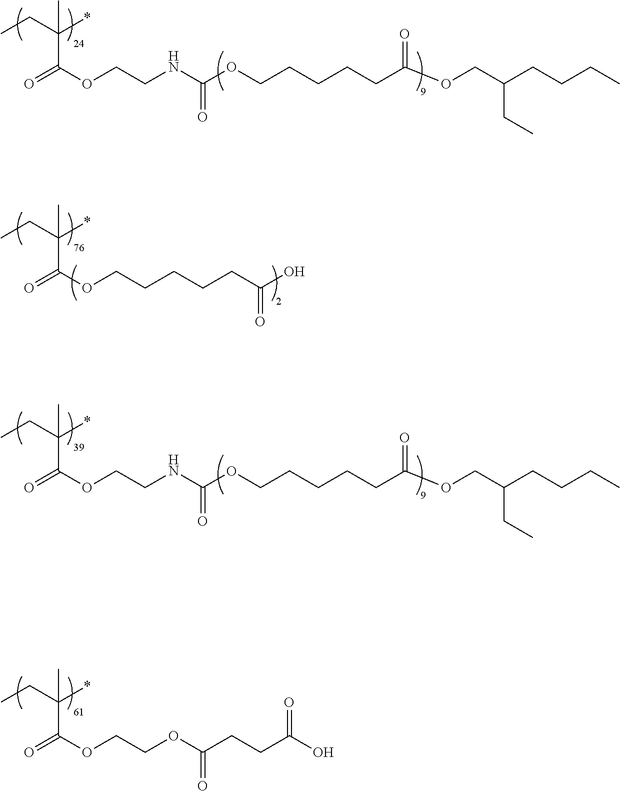

It is preferable that the resin used as a dispersant is an oligoimine-based copolymer including a nitrogen atom in at least one of the main chain or the side chain. With regard to the oligoimine-based copolymer, reference can be made to the description in paragraph Nos. 0102 to 0174 of JP2012-255128A, the contents of which are incorporated herein by reference. The dispersant is available as a commercially available product, and specific examples thereof include Disperbyk-111 (manufactured by BYK Chemie) and SOLSPERSE 76500 (manufactured by Lubrizol Corporation). In addition, pigment dispersants described in paragraph Nos. 0041 to 0130 of JP2014-130338A can also be used, the contents of which are incorporated herein by reference.

The content of the resin in the total solid content of the photosensitive composition is preferably 10% to 60% by mass. The upper limit is preferably 50% by mass or less and more preferably 40% by mass or less. The lower limit is preferably 15% by mass or more and more preferably 20% by mass or more.

The content of the resin (resin (A)) having solubility which decreases in the organic solvent due to the action of acid, in the total amount of resins included in the photosensitive composition is preferably 40% by mass or more, more preferably 50% by mass or more, still more preferably 60% by mass or more, even more preferably 70% by mass or more, particularly preferably 80% by mass or more, and most preferably 90% by mass or more. The upper limit may be 100% by mass.

The content of the resin (A) in the total solid content of the photosensitive composition is preferably 10% to 60% by mass. The upper limit is preferably 50% by mass or less and more preferably 40% by mass or less. The lower limit is preferably 15% by mass or more and more preferably 20% by mass or more.

The total content of the resin and the coloring material in the total solid content of the photosensitive composition is preferably 50% to 99% by mass. The upper limit is preferably 95% by mass or less and more preferably 90% by mass or less. The lower limit is preferably 60% by mass or more and more preferably 70% by mass or more.

<<Photoacid Generator>>

The photosensitive composition according to the embodiment of the present invention contains a photoacid generator. The photoacid generator is a compound which generates an acid in a case of being irradiated with actinic rays or radiation. As the photoacid generator used in the present invention, a compound which generates an acid having a pKa of 4 or less in a case of being irradiated with actinic rays or radiation is preferable, a compound which generates an acid having a pKa of 3 or less is more preferable, a compound which generates an acid having a pKa of 2 or less is still more preferable, and a compound which generates an acid having a pKa of −1 or less is particularly preferable. In the present invention, the pKa basically indicates a pKa in water at 25° C. In a case where the pKa cannot be measured in water, the pKa indicates a pKa which is measured in a solvent suitable for measurement, instead of water. Specifically, pKa described in a chemical handbook or the like can be referred to. As the acid having a pKa of 4 or less, a sulfonic acid or a phosphonic acid is preferable, and a sulfonic acid is more preferable.

Examples of the photoacid generator include onium salt compounds, trichloromethyl-s-triazines, sulfonium salts, iodonium salts, quaternary ammonium salts, diazomethane compounds, imide sulfonate compounds, and oxime sulfonate compounds. Among these, onium salt compounds, imide sulfonate compounds, or oxime sulfonate compounds are preferable, onium salt compounds or oxime sulfonate compounds are more preferable, and oxime sulfonate compounds are particularly preferable. With regard to details of the photoacid generator, reference can be made to the description in paragraph Nos. 0082 to 0172 of JP2011-221494A, paragraph Nos. 0084 to 0122 of JP2016-189006A, paragraph Nos. 0440 to 0509 of WO2016/136481A, paragraph Nos. 0048 to 0055 of JP2016-206503A, and paragraph Nos. 0210 to 0320 of JP2017-126044A, the contents of which are incorporated herein by reference.

Examples of a suitable aspect of the photoacid generator include compounds represented Formulae (ZI), (ZII), and (ZIII).

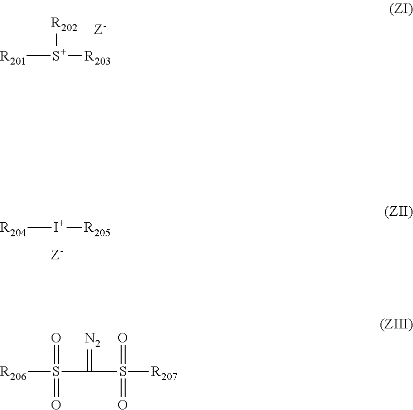

In Formula (ZI), R₂₀₁, R₂₀₂, and R₂₀₃ each independently represent an organic group. The organic group represented by R₂₀₁, R₂₀₂, and R₂₀₃ preferably has 1 to 30 carbon atoms and more preferably has 1 to 20 carbon atoms. Examples of the organic group represented by R₂₀₁, R₂₀₂, and R₂₀₃ include an aryl group and an alkyl group. The aryl group of R₂₀₁, R₂₀₂, and R₂₀₃ may be an aryl group which has a heterocyclic structure having an oxygen atom, a nitrogen atom, a sulfur atom, or the like. Examples of a skeleton of the aryl group which has a heterocyclic structure include pyrrole, furan, thiophene, indole, benzofuran, and benzothiophene. The alkyl group of R₂₀₁, R₂₀₂, and R₂₀₃ may be any of linear, branched, and cyclic forms. As the organic group of R₂₀₁, R₂₀₂, and R₂₀₃, an aryl group having 6 to 14 carbon atoms, a linear alkyl group having 1 to 15 carbon atoms, a branched alkyl group having 3 to 15 carbon atoms, or a cyclic alkyl group having 3 to 15 carbon atoms is preferable. The above-described aryl group and alkyl group may further have a substituent. Examples of the substituent include a nitro group, a halogen atom such as a fluorine atom, a carboxyl group, a hydroxyl group, an amino group, a cyano group, an alkoxy group (preferably an alkoxy group having 1 to 15 carbon atoms), an alkoxycarbonyl group (preferably an alkoxycarbonyl group having 2 to 7 carbon atoms), an acyl group (preferably an acyl group having 2 to 12 carbon atoms), an alkoxycarbonyloxy group (preferably an alkoxycarbonyloxy group having 2 to 7 carbon atoms), a thioalkyl group, and a thioaryl group, but the substituent is not limited thereto.

In Formula (ZI), two of R₂₀₁ to R₂₀₃ may be bonded to each other to form a ring structure, and the ring structure to be formed may include an oxygen atom, a sulfur atom, an ester bond, an amide bond, or a carbonyl group in the ring. Examples of a group formed by bonding two of R₂₀₁ to R₂₀₃ to each other include an alkylene group (for example, a butylene group and a pentylene group). With regard to Formula (ZI), reference can be made to the description in paragraph Nos. 0214 to 0267 of JP2017-126044A, the contents of which are incorporated herein by reference.

In Formulae (ZII) and (ZIII), R₂₀₄ to R₂₀₇ each independently represent an aryl group or an alkyl group. As the aryl group of R₂₀₄ to R₂₀₇, a phenyl group or a naphthyl group is preferable, and a phenyl group is more preferable. The aryl group of R₂₀₄ to R₂₀₇ may be an aryl group which has a heterocyclic structure having an oxygen atom, a nitrogen atom, a sulfur atom, or the like. Examples of a skeleton of the aryl group which has a heterocyclic structure include pyrrole, furan, thiophene, indole, benzofuran, and benzothiophene. Preferred examples of the alkyl group of R₂₀₄ to R₂₀₇ include a linear alkyl group having 1 to 10 carbon atoms, a branched alkyl group (for example, a methyl group, an ethyl group, a propyl group, a butyl group, and a pentyl group) having 3 to 10 carbon atoms, and a cyclic alkyl group (for example, a cyclopentyl group, a cyclohexyl group, and a norbornyl group) having 3 to 10 carbon atoms.

The aryl group and alkyl group of R₂₀₄ to R₂₀₇ may each independently have a substituent. Examples of the substituent which may be included in the aryl group and alkyl group of R₂₀₄ to R₂₀₇ include an alkyl group, an aryl group, an alkoxy group, a halogen atom, a hydroxyl group, and a phenylthio group.

In Formula (ZI) and Formula (ZII), Z⁻ represents an anion. Z⁻ in Formula (ZI) and Z⁻ in Formula (ZII) are preferably a non-nucleophilic anion (anion having extremely low ability to cause a nucleophilic reaction). Examples of the non-nucleophilic anion include a sulfonate anion (such as an aliphatic sulfonate anion, aromatic sulfonate anion, and a camphorsulfonate anion), a carboxylate anion (such as an aliphatic carboxylate anion, an aromatic carboxylate anion, and an aralkyl carboxylate anion), a sulfonylimide anion, a bis(alkylsulfonyl)imide anion, and a tris(alkylsulfonyl)methide anion.

The aliphatic site in the aliphatic sulfonate anion and the aliphatic carboxylate anion is preferably an alkyl group. The alkyl group may be any of linear, branched, and cyclic forms. The alkyl group preferably has 1 to 30 carbon atoms.

As the aromatic group in the aromatic sulfonate anion and the aromatic carboxylate anion, an aryl group having 6 to 14 carbon atoms is preferable. Specific examples thereof include a phenyl group, a tolyl group, and a naphthyl group.

The above-mentioned alkyl group and aryl group may have a substituent. Specific examples of the substituent include a nitro group, a halogen atom such as a fluorine atom, a carboxyl group, a hydroxyl group, an amino group, a cyano group, an alkoxy group (preferably having 1 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), and an alkyloxyalkyloxy group (preferably having 5 to 20 carbon atoms). Regarding the aryl group and ring structure of each group, an alkyl group (preferably having 1 to 15 carbon atoms) can be exemplified as a further substituent.

Examples of the sulfonylimide anion include a saccharin anion.

As the alkyl group in the bis(alkylsulfonyl)imide anion and the tris(alkylsulfonyl)methide anion, an alkyl group having 1 to 5 carbon atoms is preferable. The alkyl group may have a substituent. Examples of the substituent include a halogen atom, an alkyl group substituted with a halogen atom, an alkoxy group, an alkylthio group, an alkyloxysulfonyl group, an aryloxysulfonyl group, and a cycloalkylaryloxysulfonyl group, and a fluorine atom or an alkyl group substituted with a fluorine atom is preferable. In addition, the alkyl groups in the bis(alkylsulfonyl)imide anion may be bonded to each other to form a ring structure.

Examples of other non-nucleophilic anions include fluorinated phosphorus (for example, PF₆⁻), fluorinated boron (for example, BF₄⁻), and fluorinated antimony (for example, SbF₆⁻).

As the non-nucleophilic anion, an aliphatic sulfonate anion in which at least an α-position of the sulfonic acid is substituted with a fluorine atom, an aromatic sulfonate anion substituted with a fluorine atom or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom is preferable. As the non-nucleophilic anion, a perfluoroaliphatic sulfonate anion (preferably having 4 to 8 carbon atoms) or a benzenesulfonate anion having a fluorine atom is more preferable, and a nonafluorobutane sulfonate anion, a perfluorooctane sulfonate anion, a pentafluorobenzene sulfonate anion, or 3,5-bis(trifluoromethyl)benzene sulfonate anion is more preferable. In addition, with regard to the non-nucleophilic anion, reference can be made to the description in paragraph Nos. 0269 to 0310 of JP2017-126044A, the contents of which are incorporated herein by reference.

Preferred examples of the sulfonium cation in Formula (ZI) and the iodonium cation in Formula (ZII) are shown below.

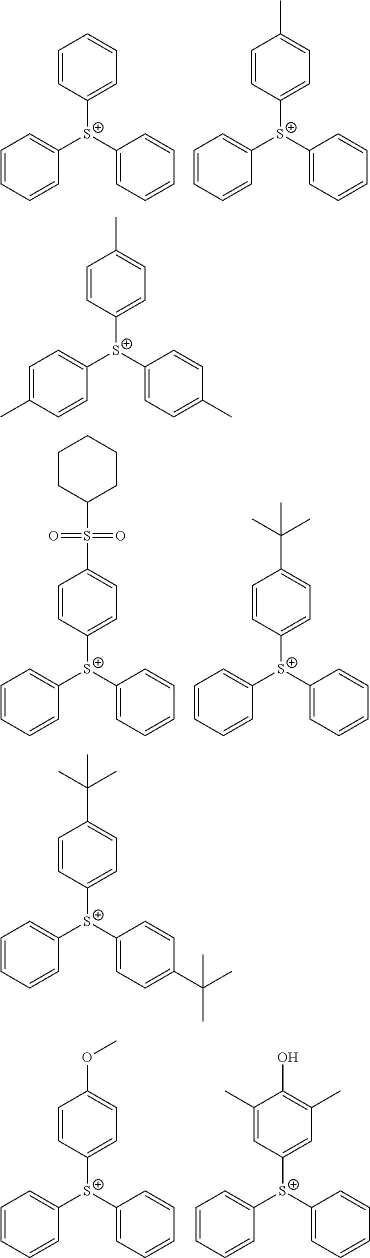

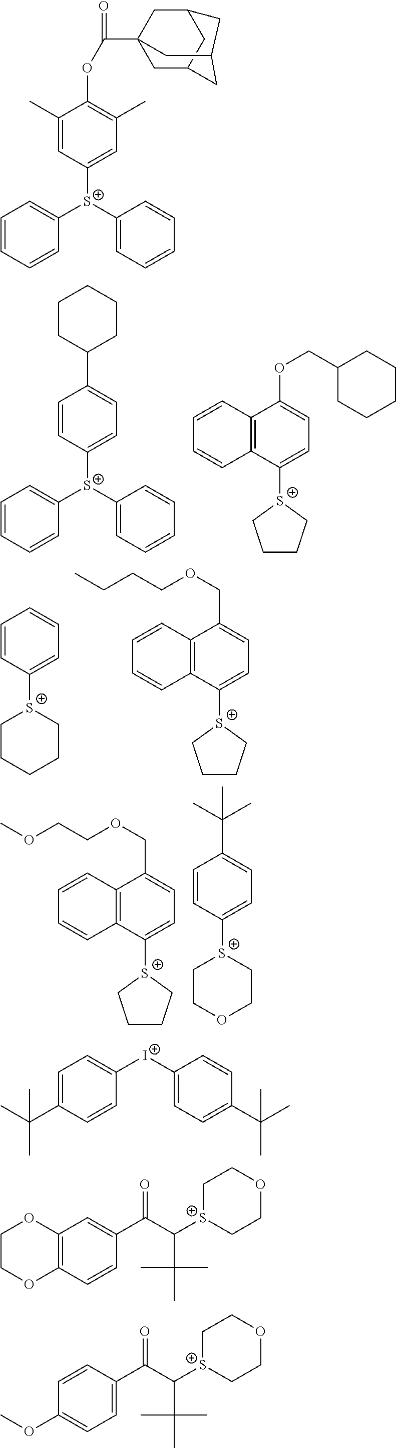

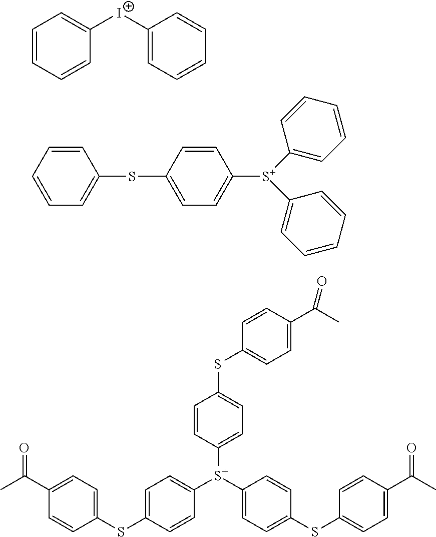 [SMILES: c1ccc([I+]c2ccccc2)cc1 ; c1ccc(Sc2ccc([S+](c3ccccc3)c3ccccc3)cc2)cc1 ; CC(=O)c1ccc(Sc2ccc([S+](c3ccc(Sc4ccc(C(C)=O)cc4)cc3)c3ccc(Sc4ccc(C(C)=O)cc4)cc3)cc2)cc1]

Preferred examples of the anion Z⁻ in Formula (ZI) and Formula (ZII) are shown below.

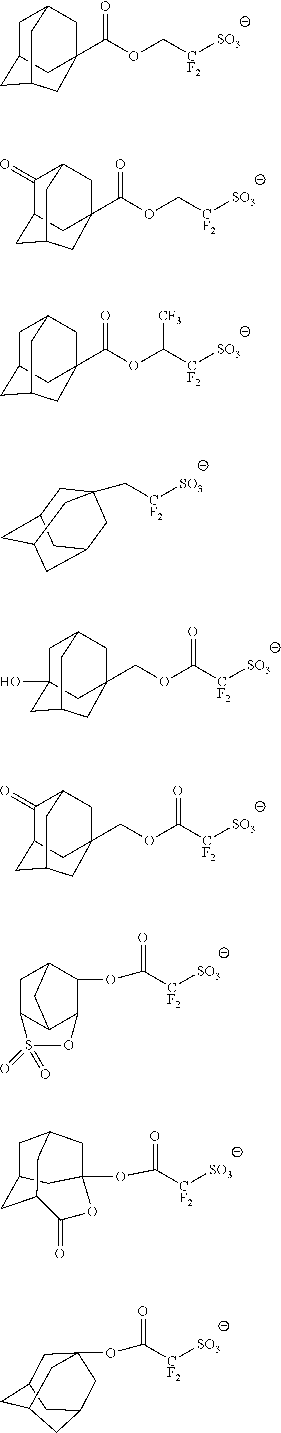

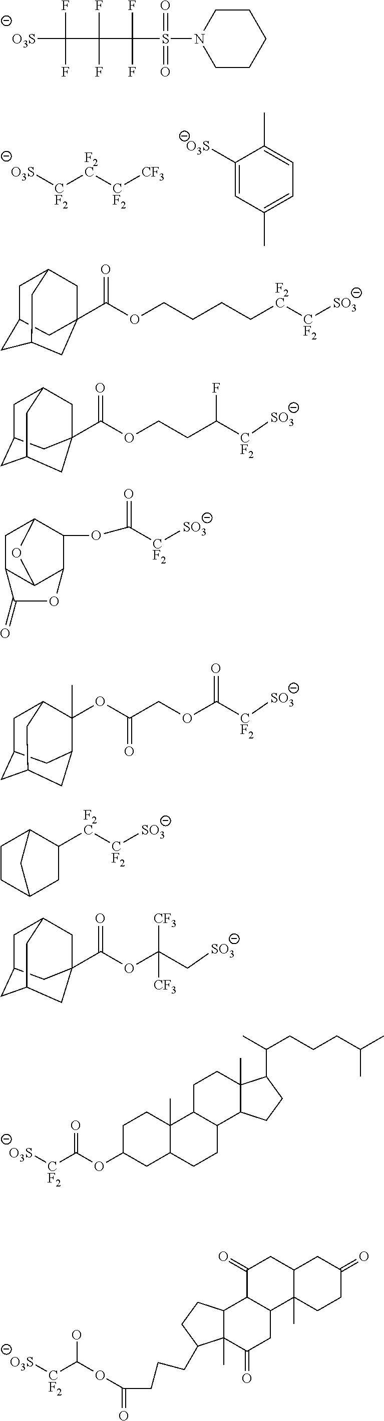

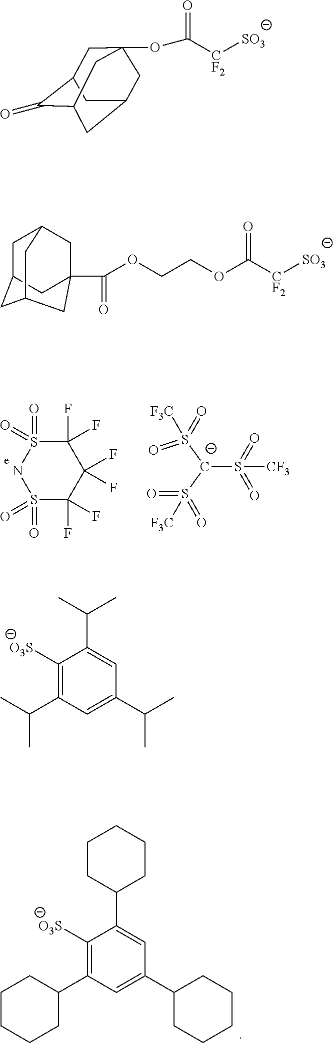

A photoacid generator having any combination of the above-described cation and anion can be used. Specific examples of the photoacid generator include compounds described in paragraph Nos. 0315 to 0320 of JP2017-126044A.

In the present invention, an oxime sulfonate compound is also preferably used as the photoacid generator. Preferred examples of the oxime sulfonate compound include a compound including an oxime sulfonate structure represented by Formula (OS-1).

(OS-1)

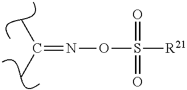

In Formula (OS-1), R²¹ represents an alkyl group or an aryl group. The wavy line represents a direct bond with another group or atom constituting the oxime sulfonate compound.

The alkyl group and aryl group represented by R²¹ in Formula (OS-1) may have a substituent, or may be unsubstituted. In a case where R²¹ is an alkyl group, R²¹ is preferably a linear or branched alkyl group having 1 to 10 carbon atoms. The alkyl group of R²¹ may be substituted with a halogen atom, an aryl group having 6 to 11 carbon atoms, an alkoxy group having 1 to 10 carbon atoms, or a cyclic alkyl group (including a bridged alicyclic group such as a 7,7-dimethyl-2-oxonorbornyl group, preferably a bicycloalkyl group or the like). In a case where R²¹ represents an aryl group, R²¹ is preferably an aryl group having 6 to 11 carbon atoms, and more preferably a phenyl group or a naphthyl group. The aryl group of R²¹ may be substituted with an alkyl group, an alkoxy group, or a halogen atom. With regard to details of the compound including the oxime sulfonate structure represented by Formula (OS-1), reference can be made to the description in paragraph Nos. 0066 to 0098 of WO2016/175220A, the contents of which are incorporated herein by reference.

The photoacid generator used in the present invention may be a form of a low-molecular-weight compound, or may be a form of being incorporated in a part of a polymer. In addition, the form of a low-molecular-weight compound and the form of being incorporated in a part of a polymer may coexist. The photoacid generator is preferably the form of a low-molecular-weight compound. In a case where the photoacid generator is the form of a low-molecular-weight compound, the molecular weight is preferably 3,000 or less, more preferably 2,000 or less, and still more preferably 1,000 or less.

The content of the photoacid generator in the total solid content of the photosensitive composition is preferably 0.1% to 20% by mass. The lower limit is preferably 0.5% by mass or more, more preferably 1% by mass or more, and still more preferably 2% by mass or more. The upper limit is preferably 15% by mass or less, more preferably 10% by mass or less, still more preferably 8% by mass or less, and particularly preferably 5% by mass or less.

In addition, the content of the photoacid generator is preferably 0.1 to 50 parts by mass with respect to 100 parts by mass of the above-described resin (A). The lower limit is preferably 0.5 parts by mass or more, more preferably 1 part by mass or more, and still more preferably 2 parts by mass or more. The upper limit is preferably 40 parts by mass or less, more preferably 30 parts by mass or less, and still more preferably 20 parts by mass or less.

In addition, in a case where the photosensitive composition according to the embodiment of the present invention contains the acid crosslinking agent described later, the content of the photoacid generator is preferably 0.1 to 50 parts by mass with respect to 100 parts by mass in total of the above-described resin (A) and the acid crosslinking agent. The lower limit is preferably 0.5 parts by mass or more, more preferably 1 part by mass or more, and still more preferably 2 parts by mass or more. The upper limit is preferably 40 parts by mass or less, more preferably 30 parts by mass or less, and still more preferably 20 parts by mass or less.

The photoacid generator may be used singly or in combination of two or more kinds thereof. In a case where two or more kinds thereof are used in combination, the total amount thereof is preferably within the above-described range.

<<Acid Diffusion Control Agent>>

The photosensitive composition can contain an acid diffusion control agent. The acid diffusion control agent acts as a quencher trapping the acid generated from the photoacid generator in a case of exposure and suppressing the reaction in the above-described resin (A) on an unexposed area due to excessively generated acid. As the acid diffusion control agent, a basic compound, a low-molecular-weight compound having a nitrogen atom and having a group eliminated due to the action of acid, a basic compound, basicity of which decreases or disappears due to the irradiation with actinic rays or radiation, or an onium salt which is relatively a weak acid to the photoacid generator can be used.

Preferred examples of the basic compound include compounds having structures represented by Formulae (A) to (E).

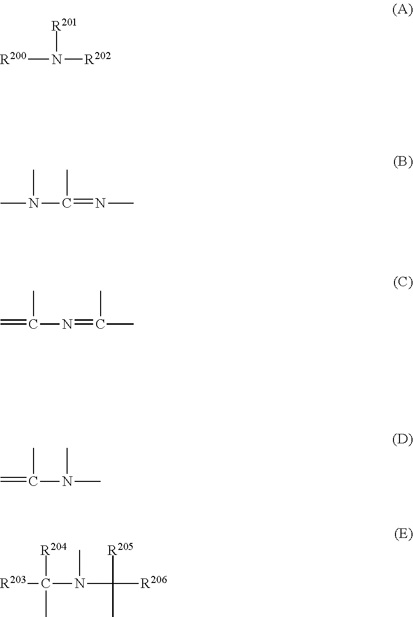

In Formulae (A) and (E), R²⁰⁰, R²⁰¹, and R²⁰² may be the same as or different from each other, and represent a hydrogen atom, an alkyl group, or an aryl group, in which R²⁰¹ and R²⁰² may be bonded to each other to form a ring. R²⁰³, R²⁰⁴, R²⁰⁵ and R²⁰⁶ may be the same as or different from each other, and represent an alkyl group having 1 to 20 carbon atoms.

In the above-mentioned alkyl group, as an alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

The alkyl groups in Formulae (A) and (E) are more preferably unsubstituted.

Specific examples of the basic compound include guanidine, aminopyrrolidine, pyrazole, pyrazoline, piperazine, aminomorpholine, aminoalkylmorpholine, and piperidine. In addition, examples of the basic compound include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond.

In addition, as the basic compound, an amine compound having a phenoxy group, an ammonium salt compound having a phenoxy group, an amine compound having a sulfonic acid ester group, or an ammonium salt compound having a sulfonic acid ester group can be preferably used. With regard to details thereof, reference can be made to the description in paragraph Nos. 0307 to 0311 of WO2016/104565A, the contents of which are incorporated herein by reference.

In a case where the photosensitive composition contains a basic compound, the content of the basic compound is preferably 0.001% to 10% by mass and more preferably 0.01% to 5% by mass with respect to the total solid content of the photosensitive composition. In addition, in the photosensitive composition, the proportion of the photoacid generator (in a case of a plurality of photoacid generators, the total thereof) and the basic compound is preferably, in a molar ratio, photoacid generator/basic compound=2.5 to 300. From the viewpoint of sensitivity and resolution, the above-described molar ratio is preferably 2.5 or more, and from the viewpoint of suppressing the deterioration in resolution due to the thickening of a resist pattern with the passage of time from the exposure to the heat treatment, the above-described molar ratio is preferably 300 or less. The above-described molar ratio is more preferably 5.0 to 200 and still more preferably 7.0 to 150.

As the low-molecular-weight compound (hereinafter, also referred to as a “compound (D-1)”) having a nitrogen atom and having a group eliminated due to the action of acid, an amine derivative having, on a nitrogen atom, the group eliminated due to the action of acid is preferable. As the group eliminated due to the action of acid, an acetal group, a carbonate group, a carbamate group, a tertiary ester group, a tertiary hydroxyl group, or a hemiaminal ether group is preferable, and a carbamate group or a hemiaminal ether group is particularly preferable. The molecular weight of the compound (D-1) is preferably 100 to 1,000, more preferably 100 to 700, and particularly preferably 100 to 500.

The compound (D-1) may have a carbamate group having a protecting group on the nitrogen atom. The protecting group constituting the carbamate group can be represented by Formula (d-1).

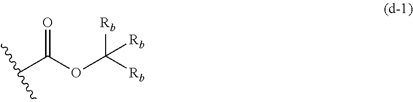

In Formula (d-1), R_{b}′ each independently represent a hydrogen atom, an alkyl group, an aryl group, an aralkyl group, or an alkoxyalkyl group. R_{b}'s may be linked to each other to form a ring.

The alkyl group, aryl group, and aralkyl group represented by R_{b} may be substituted with a functional group such as a hydroxy group, a cyano group, an amino group, a pyrrolidino group, a piperidino group, a morpholino group, and an oxo group, an alkoxy group, or a halogen atom. The same applies to the alkoxyalkyl group represented by R_{b}. As R_{b}, the alkyl group or the aryl group is preferable. The alkyl group is more preferable. Examples of the ring formed by linking two R_{b}'s to each other include an alicyclic hydrocarbon group, an aromatic hydrocarbon group, a heterocyclic hydrocarbon group, and a derivative thereof. Examples of a specific structure of the group represented by Formula (d-1) include structures disclosed in paragraph No. 0466 of US2012/0135348A, the contents of which are incorporated herein by reference.

It is preferable that the compound (D-1) is a compound having a structure represented by Formula (6).

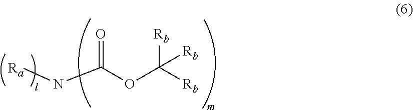

In Formula (6), Rₐ represents a hydrogen atom, an alkyl group, an aryl group, or an aralkyl group. In a case where 1 is 2, two Rₐ's may be the same as or different from each other, and two Rₐ's may be linked to each other to form a hetero ring with the nitrogen atom in the formula. The hetero ring may include a heteroatom other than the nitrogen atom in the formula. R_{b} has the same meaning as R_{b} in Formula (d-1), and the preferred examples are also the same. 1 represents an integer of 0 to 2, m represents an integer of 1 to 3, and 1+m satisfies 3. In Formula (6), the alkyl group, aryl group, and aralkyl group as Rₐ may be substituted with the same group as described in the group with which the alkyl group, aryl group, and aralkyl group as R_{b} may be substituted.

Specific examples of the compound (D-1) include compounds described in paragraph No. 0475 of US2012/0135348A, the contents of which are incorporated herein by reference.

The compound represented by Formula (6) can be synthesized based on JP2007-298569A, JP2009-199021A, and the like.

Examples of the basic compound (hereinafter, also referred to as a “compound (PA)”), basicity of which decreases or disappears due to the irradiation with actinic rays or radiation, include a compound which has a proton acceptor functional group and decomposes due to the irradiation with actinic rays or radiation, so that proton acceptor property decreases or disappears, or is changed to acid property.

The proton acceptor functional group is a group capable of electrostatically interacting with a proton, or a functional group having an electron, and for example, the proton acceptor functional group means a functional group having a macrocyclic structure such as a cyclic polyether, or a functional group having a nitrogen atom with an unshared electron pair which does not contribute to π-conjugation. The nitrogen atom with an unshared electron pair which does not contribute to π-conjugation is, for example, a nitrogen atom having a partial structure represented by the following formula.

[symbol]

[symbol]

[symbol]

Unshared electron pair

Examples of a preferred partial structure of the proton acceptor functional group include a structure of crown ether, azacrown ether, primary to tertiary amine, pyridine, imidazole, or pyrazine.

The compound (PA) generates a compound which decomposes due to the irradiation with actinic rays or radiation, so that proton acceptor property decreases or disappears, or is changed to acid property. Here, the decrease or disappearance of proton acceptor property, or the change from proton acceptor property to acid property is a change in proton acceptor property due to the proton being added to the proton acceptor functional group, and specifically means that, in a case where a proton adduct is generated from the compound (PA) having the proton acceptor functional group and the proton, the equilibrium constant in chemical equilibrium thereof decreases. The proton acceptor property can be confirmed by performing a pH measurement. With regard to the compound (PA), reference can be made to the description in paragraph Nos. 0312 to 0320 of WO2016/104565A, the contents of which are incorporated herein by reference.

In the photosensitive composition, an onium salt which is relatively a weak acid to the photoacid generator can be used as the acid diffusion control agent. In a case where a photoacid generator is mixed and used with an onium salt generating an acid which is relatively a weak acid (preferably a weak acid having a pKa of more than −1) to an acid generated from the photoacid generator, the acid generated from the photoacid generator due to the irradiation with actinic rays or radiation collides with an onium salt having an unreacted weak-acid anion, therefore salt exchange releases the weak acid to yield an onium salt with a strong-acid anion. In this process, since the strong acid is exchanged for the weak acid having a lower catalytic ability, the acid is apparently deactivated and the acid diffusion can be controlled. With regard to these compounds, reference can be made to the description in paragraph Nos. 0191 to 0210 of JP2012-242799A, paragraph Nos. 0037 to 0039 of JP2013-006827A, paragraph Nos. 0027 to 0029 of JP2013-008020A, paragraph Nos. 0012 and 0013 of JP2012-189977A, and paragraph Nos. 0029 to 0031 of JP2012-252124A, the contents of which are incorporated herein by reference.

In a case where the photosensitive composition according to the embodiment of the present invention contains an acid diffusion control agent, the content of the acid diffusion control agent in the total solid content of the photosensitive composition is preferably 0.1% to 10% by mass. The lower limit is preferably 0.5% by mass or more and more preferably 1% by mass or more. The upper limit is preferably 8% by mass or less and still more preferably 5% by mass or less.

<<Acid Crosslinking Agent>>

The photosensitive composition according to the embodiment of the present invention preferably contains an acid crosslinking agent. According to this aspect, a film having a high crosslinking density can be formed, and a film excellent in various characteristics such as heat resistance, solvent resistance, and strength is easily formed. In the present specification, an acid crosslinking agent refers to a crosslinking agent which crosslinks by the action of acid.

The acid crosslinking agent is not particularly limited as long as a crosslinking reaction can occur by the action of acid so as to cure a film. Examples thereof include a compound having one or more of at least one group selected from an epoxy group, a methylol group, an alkoxymethyl group, and an acyloxymethyl group, and a compound having one or more epoxy groups is preferable.

Examples of the compound having an epoxy group include a compound having one or more epoxy groups in one molecule, and a compound two or more epoxy groups in one molecule is preferable. It is preferable to have 1 to 100 epoxy groups in one molecule. The upper limit of the number of epoxy groups is, for example, 10 or less or 5 or less. The lower limit of the number of epoxy groups is preferably 2 or more.

The compound having an epoxy group may be either a low-molecular-weight compound (for example, having a molecular weight of less than 2,000, and further, a molecular weight of less than 1,000) or a high-molecular-weight compound (macromolecule) (for example, having a molecular weight of 1,000 or more, and in a case of a polymer, having a weight-average molecular weight of 1,000 or more). The weight-average molecular weight of the compound having an epoxy group is preferably 200 to 100,000 and more preferably 500 to 50,000. The upper limit of the weight-average molecular weight is preferably 10,000 or less, more preferably 5,000 or less, and still more preferably 3,000 or less.

In a case where the compound having an epoxy group is a low-molecular-weight compound, examples thereof include a compound represented by Formula (EP1).

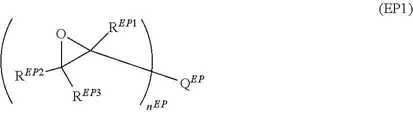

In Formula (EP1), R^{EP1} to R^{EP3} respectively represent a hydrogen atom, a halogen atom, or an alkyl group, in which the alkyl group may have a cyclic structure and the alkyl group may have a substituent. In addition, R^{EP1} and R^{EP2}, or R^{EP2} and R^{EP3} may be bonded to each other to form a ring structure. Q^{EP} represents a single bond or an n^{EP}-valent organic group. R^{EP1} to R^{EP3} may be bonded to Q^{EP} to form a ring structure. n^{EP} represents an integer of 2 or more, preferably 2 to 10, and still more preferably 2 to 6. However, in a case where Q^{EP} is a single bond, n^{EP} is 2. With regard to details of R^{EP1} to R^{EP3}, and Q^{EP}, reference can be made to the description in paragraph Nos. 0087 and 0088 of JP2014-089408A, the contents of which are incorporated herein by reference. Specific examples of the compound represented by Formula (EP1) include the compounds described in paragraph 0090 of JP2014-089408A, and paragraph No. 0151 of JP2010-054632A, the contents of which are incorporated herein by reference.

Examples of a commercially available product of the low-molecular-weight compound include ADEKA GLYCIROL series (for example, ADEKA GLYCIROL ED-505 and the like) manufactured by ADEKA Corporation, and EPOLEAD series (for example, EPOLEAD GT401 and the like) manufactured by Daicel Corporation.

As the compound having an epoxy group, an epoxy resin can be preferably used. Examples of the epoxy resin include an epoxy resin which is a glycidyl etherified product of a phenol compound, an epoxy resin which is a glycidyl etherified product of various novolak resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the epoxy resin include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation, an epoxy group-containing polymer).

As the compound having an epoxy group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

Examples of the compound having a methylol group (hereinafter, also referred to as a methylol compound) include a compound in which a methylol group is bonded to a nitrogen atom or a carbon atom which forms an aromatic ring. In addition, examples of the compound having an alkoxymethyl group (hereinafter, also referred to as an alkoxymethyl compound) include a compound in which an alkoxymethyl group is bonded to a nitrogen atom or a carbon atom which forms an aromatic ring. In addition, examples of the compound having an acyloxymethyl group (hereinafter, also referred to as an acyloxymethyl compound) include a compound in which an acyloxymethyl group is bonded to a nitrogen atom or a carbon atom which forms an aromatic ring. Examples of the methylol compound, the alkoxymethyl compound, and the acyloxymethyl compound include a melamine compound, a guanamine compound, a glycoluril compound, a urea compound, a phenol compound, a naphthol compound, and a hydroxyanthracene compound, each of which is substituted with at least one group selected from the methylol group, the alkoxymethyl group, and the acyloxymethyl group.

As the melamine compound substituted with the above-described group, a melamine compound having 2 to 6 of the above-described groups is preferable, and a melamine compound having 5 or 6 of the above-described groups is more preferable. The glycoluril compound substituted with the above-described group preferably has 2 to 4 of the above-described groups, and more preferably has 3 or 4 of the above-described groups. The guanamine compound substituted with the above-described group preferably has 2 to 4 of the above-described groups, and more preferably has 3 or 4 of the above-described groups. The urea compound substituted with the above-described group preferably has 2 to 4 of the above-described groups, and more preferably has 3 or 4 of the above-described groups. In the phenol compound substituted with the above-described group, it is preferable that at least a part of a 2-position or a 4-position of a phenol compound skeleton is substituted with the above-described group, and it is more preferable that all of the 2-position and the 4-position of the phenol compound skeleton are substituted with the above-described group. In the naphthol compound substituted with the above-described group, it is preferable that at least a part of an ortho position or a para position of OH group is substituted with the above-described group, and it is more preferable that all of the ortho position and the para position of OH group are substituted with the above-described group. In the hydroxyanthracene compound substituted with the above-described group, it is preferable that at least a part of an ortho position or a para position of OH group is substituted with the above-described group, and it is more preferable that all of the ortho position and the para position of OH group are substituted with the above-described group.

With regard to details of the methylol compound, the alkoxymethyl compound, and the acyloxymethyl compound, reference can be made to the description in paragraph Nos. 0126 to 0134 of JP2011-039319A, the contents of which are incorporated herein by reference.

In a case where the photosensitive composition according to the embodiment of the present invention contains an acid crosslinking agent, the content of the acid crosslinking agent in the total solid content of the photosensitive composition is preferably 0.1% to 30% by mass. The lower limit is preferably 0.5% by mass or more and more preferably 1% by mass or more. The upper limit is preferably 25% by mass or less and still more preferably 20% by mass or less.

In addition, the content of the acid crosslinking agent is preferably 0.1 to 50 parts by mass with respect to 100 parts by mass of the above-described resin (A). The lower limit is preferably 0.5 parts by mass or more, more preferably 1 part by mass or more, and still more preferably 2 parts by mass or more. The upper limit is preferably 40 parts by mass or less, more preferably 30 parts by mass or less, and still more preferably 20 parts by mass or less.

In addition, the total content of the above-described resin (A) and the acid crosslinking agent in the total solid content of the photosensitive composition is preferably 10% to 60% by mass. The lower limit is preferably 15% by mass or more and more preferably 20% by mass or more. The upper limit is preferably 50% by mass or less and still more preferably 40% by mass or less.

Only one kind of acid crosslinking agent may be included, or two or more kinds thereof may be included. In a case where two or more kinds thereof are included, the total amount thereof is preferably within the above-described range.

<<Radical Polymerizable Monomer>>

The photosensitive composition according to the embodiment of the present invention may contain a radical polymerizable monomer. The radical polymerizable monomer is not particularly limited as long as the radical polymerizable monomer is a compound which can be polymerized by the action of radical. As the radical polymerizable monomer, a compound which has one or more groups having an ethylenically unsaturated bond is preferable, a compound which has two or more groups having an ethylenically unsaturated bond is more preferable, and a compound which has three or more groups having an ethylenically unsaturated bond is still more preferable. The upper limit of the number of groups having an ethylenically unsaturated bond is, for example, preferably 15 or less and more preferably 6 or less. Examples of the group having an ethylenically unsaturated bond include a vinyl group, a (meth)allyl group, and a (meth)acryloyl group, and a (meth)acryloyl group is preferable. The radical polymerizable monomer is preferably a 3-functional to 15-functional (meth)acrylate compound and more preferably a 3-functional to 6-functional (meth)acrylate compound.

The molecular weight of the radical polymerizable monomer is preferably 200 to 3,000. The upper limit of the molecular weight is preferably 2,000 or less and still more preferably 1,500 or less. The lower limit of the molecular weight is preferably 250 or more and still more preferably 300 or more.

In the photosensitive composition according to the embodiment of the present invention, the content of the radical polymerizable monomer in the total solid content of the photosensitive composition is preferably 5% by mass or less, more preferably 4% by mass or less, still more preferably 3% by mass or less, even more preferably 2% by mass or less, and particularly preferably 1% by mass or less. In addition, it is also preferable that the photosensitive composition according to the embodiment of the present invention does not substantially include the radical polymerizable monomer. According to this aspect, crosslinking is less likely to occur even in a case where exposure light reaches a portion required to be unexposed due to a light leak or the like, and the effect of further improving rectangularity can be expected. The case where the photosensitive composition according to the embodiment of the present invention does not substantially include the radical polymerizable monomer means that the content of the radical polymerizable monomer in the total solid content of the photosensitive composition is 0.5% by mass or less, preferably 0.1% by mass or less, more preferably 0.01% by mass or less, and still more preferably 0% by mass.

<<Photoradical Polymerization Initiator>>

The photosensitive composition according to the embodiment of the present invention may contain a photoradical polymerization initiator. Examples of the photoradical polymerization initiator include a trihalomethyl triazine compound, a benzyl dimethyl ketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, and a coumarin compound, and an oxime compound, an α-hydroxyketone compound, an α-aminoketone compound, or an acylphosphine compound is preferable and an oxime compound or an α-aminoketone compound is more preferable. With regard to details of the photoradical polymerization initiator, reference can be made to the description in paragraph Nos. 0013 to 0031 of JP2017-126044A, the contents of which are incorporated herein by reference.

In the photosensitive composition according to the embodiment of the present invention, the content of the photoradical polymerization initiator in the total solid content of the photosensitive composition is preferably 4% by mass or less, more preferably 2% by mass or less, still more preferably 1% by mass or less, even more preferably 0.5% by mass or less, and particularly preferably 0.05% by mass or less. In addition, it is also preferable that the photosensitive composition according to the embodiment of the present invention does not substantially include the photoradical polymerization initiator. According to this aspect, crosslinking is less likely to occur even in a case where exposure light reaches a portion required to be unexposed due to a light leak or the like, and the effect of further improving rectangularity can be expected. The case where the photosensitive composition according to the embodiment of the present invention does not substantially include the photoradical polymerization initiator means that the content of the photoradical polymerization initiator in the total solid content of the photosensitive composition is 0.01% by mass or less, preferably 0.005% by mass or less, more preferably 0.001% by mass or less, and still more preferably 0% by mass.

<<Pigment Derivative>>

The photosensitive composition according to the embodiment of the present invention can contain a pigment derivative. Examples of the pigment derivative include a compound having a structure in which a part of a chromophore is substituted with an acid group, a basic group, or a phthalimidemethyl group. Examples of the chromophore constituting the pigment derivative include a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton. Among these, a quinoline-based skeleton, a benzimidazolone-based skeleton, a diketopyrrolopyrrole-based skeleton, an azo-based skeleton, a quinophthalone-based skeleton, an isoindoline-based skeleton, or a phthalocyanine-based skeleton is preferable, and an azo-based skeleton or a benzimidazolone-based skeleton is more preferable. As the acid group included in the pigment derivative, a sulfo group or a carboxyl group is preferable and a sulfo group is more preferable. As the basic group included in the pigment derivative, an amino group is preferable and a tertiary amino group is more preferable. With regard to specific examples of the pigment derivative, reference can be made to the description in paragraph Nos. 0162 to 0183 of JP2011-252065A, the contents of which are incorporated herein by reference. The content of the pigment derivative is preferably 1 to 30 parts by mass and still more preferably 3 to 20 parts by mass with respect to 100 parts by mass of the pigment. The pigment derivative may be used singly or in combination of two or more kinds thereof.

<<Solvent>>

The photosensitive composition according to the embodiment of the present invention preferably contains a solvent. The solvent is preferably an organic solvent. Specific examples of the organic solvent include acetone, methyl ethyl ketone, cyclohexane, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetylacetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxyethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, γ-butyrolactone, ethyl acetate, butyl acetate, methyl lactate, ethyl lactate, 3-methoxy-N,N-dimethylpropanamide, and 3-butoxy-N,N-dimethylpropanamide, but the organic solvent is not limited thereto. However, it is preferable in some cases to reduce aromatic hydrocarbons (benzene, toluene, xylene, ethylbenzene, and the like) (for example, the amount can be set to 50 ppm (parts per million) by mass or less, 10 ppm by mass or less, or 1 ppm by mass or less with respect to the total amount of the organic solvent) as a solvent for a reason such as an environmental aspect.

In a case where the organic solvent is used in combination of two or more kinds thereof, the solvent is particularly preferably composed of two or more kinds selected from the group consisting of methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclopentanone, ethyl carbitol acetate, butyl carbitol acetate, propylene glycol methyl ether, and propylene glycol methyl ether acetate.

In the present invention, a solvent having a low metal content is preferably used. For example, the metal content in the solvent is preferably 10 ppb (parts per billion) by mass or less. A solvent in which the metal content is at a level of ppt (parts per trillion) by mass may be used as desired, and such a high-purity solvent is provided by, for example, Toyo Kasei Kogyo Co., Ltd. (The Chemical Daily, Nov. 13, 2015).

Examples of a method for removing impurities such as a metal from the solvent include distillation (for example, molecular distillation and thin-film distillation) and filtration using a filter. The filter pore size of a filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers or a plurality of isomers may be included.

In the present invention, the organic solvent preferably has the content of peroxides of 0.8 mmol/L or less, and more preferably, the organic solvent does not substantially include peroxides.

The content of the solvent in the photosensitive composition is preferably 10% to 95% by mass. The lower limit is preferably 20% by mass or more, more preferably 30% by mass or more, still more preferably 40% by mass or more, even more preferably 50% by mass or more, and still even more preferably 60% by mass or more. The upper limit is preferably 90% by mass or less and still more preferably 85% by mass or less.

In addition, from the viewpoint of environmental regulation, it is preferable that the photosensitive composition according to the embodiment of the present invention does not substantially contain environmentally regulated substances. In the present invention, the description “does not substantially contain environmentally regulated substances” means that the content of the environmentally regulated substances in the photosensitive composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent at the time of producing respective components used in the photosensitive composition according to the embodiment of the present invention, and may be incorporated into the photosensitive composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or composition produced by mixing these compounds.

<<Surfactant>>

The photosensitive composition according to the embodiment of the present invention can contain a surfactant. As the surfactant, various surfactants such as a fluorine-based surfactant, a nonionic surfactant, a cationic surfactant, an anionic surfactant, and a silicon-based surfactant can be used. With regard to the surfactant, reference can be made to the description in paragraph Nos. 0238 to 0245 of WO2015/166779A, the contents of which are incorporated herein by reference.

In the present invention, it is preferable that the surfactant is a fluorine-based surfactant. By the photosensitive composition containing a fluorine-based surfactant, liquid characteristics (in particular, fluidity) are further improved, and liquid saving properties can be further improved. In addition, a film with small thickness unevenness can be formed.

The fluorine content in the fluorine-based surfactant is preferably 3% to 40% by mass, more preferably 5% to 30% by mass, and still more preferably 7% to 25% by mass. The fluorine-based surfactant in which the fluorine content is within the above-described range is effective in terms of the evenness of the thickness of the coating film or liquid saving properties and the solubility of the surfactant in the photosensitive composition is also good.

Examples of the fluorine-based surfactant include surfactants described in paragraph Nos. 0060 to 0064 of JP2014-041318A (paragraph Nos 0060 to 0064 of the corresponding WO2014/017669A) and the like, and surfactants described in paragraph Nos 0117 to 0132 of JP2011-132503A, the contents of which are incorporated herein by reference. Examples of a commercially available product of the fluorine-based surfactant include MEGAFACE F171, F172, F173, F176, F177, F141, F142, F143, F144, R₃₀, F437, F475, F479, F482, F554, F780, EXP, and MFS-330 (all of which are manufactured by DIC Corporation), FLUORAD FC430, FC431, and FC171 (all of which are manufactured by Sumitomo 3M), SURFLON S-382, SC-101, SC-103, SC-104, SC-105, SC-1068, SC-381, SC-383, and S-393, and KH-40 (all of which are manufactured by Asahi Glass Co., Ltd.), and PolyFox PF₆₃₆, PF₆₅₆, PF₆₃₂₀, PF₆₅₂₀, and PF₇₀₀₂ (all of which are manufactured by OMNOVA).

As the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of the fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

As the fluorine-based surfactant, it is also preferable to use a polymer of a fluorine atom-containing vinyl ether compound having a fluorinated alkyl group or a fluorinated alkylene ether group and a hydrophilic vinyl ether compound. With regard to such a fluorine-based surfactant, reference can be made to the description in JP2016-216602A, the contents of which are incorporated herein by reference.

A block polymer can also be used as the fluorine-based surfactant. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as a fluorine-based surfactant for use in the present invention. In the following formula, % representing the proportion of the repeating unit is % by mole.

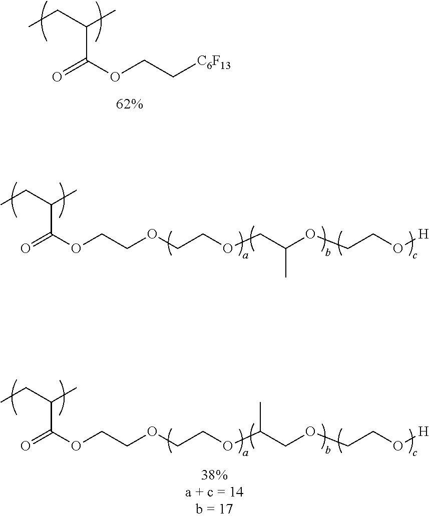

The weight-average molecular weight of the compounds is preferably 3,000 to 50,000, and is, for example, 14,000.

A fluorine-containing polymer having an ethylenically unsaturated group in the side chain can also be used as the fluorine-based surfactant. Specific examples thereof include the compounds described in paragraph Nos. 0050 to 0090 and paragraph Nos. 0289 to 0295 of JP2010-164965A. Examples of a commercially available product thereof include MEGAFACE RS-101, RS-102, RS-718-K, and RS-72-K, all manufactured by DIC Corporation.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Japan Ltd.), NCW-101, NCW-1001, and NCW-1002 (manufactured by FUJIFILM Wako Pure Chemical Corporation), PIONIN D-6112, D-6112-W, and D-6315 (manufactured by Takemoto Oil & Fat Co., Ltd.), and OLFINE E1010, and SURFYNOL 104, 400, and 440 (manufactured by Nissin Chemical Industry Co., Ltd.).

Examples of the cationic surfactant include an organosiloxane polymer KP341 (manufactured by Shin-Etsu Chemical Co., Ltd.), (meth)acrylic acid-based (co)polymers POLYFLOW No. 75, No. 90, and No. 95 (manufactured by KYOEISHA CHEMICAL CO., LTD.), and WO01 (manufactured by Yusho Co., Ltd.).

Examples of the anionic surfactant include WO04, WO05, and WO17 (manufactured by Yusho Co., Ltd.), and SANDET BL (manufactured by Sanyo Chemical Industries, Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP341, KF6001, and KF6002 (all of which are manufactured by Shin-Etsu Silicone Co., Ltd.), and BYK307, BYK323, and BYK330 (all of which are manufactured by BYK Chemie).

The content of the surfactant in the total solid content of the photosensitive composition is preferably 0.001% to 2.0% by mass and more preferably 0.005% to 1.0% by mass. The surfactant may be used singly or in combination of two or more kinds thereof. In a case where two or more kinds thereof are included, the total amount thereof is preferably within the above-described range.

<<Silane Coupling Agent>>

The photosensitive composition according to the embodiment of the present invention can contain a silane coupling agent. As the silane coupling agent, a silane compound having at least two kinds of functional groups having different reactivity in one molecule is preferable. The silane coupling agent is preferably a silane compound having at least one group selected from a vinyl group, an epoxy group, a styrene group, a methacryl group, an amino group, an isocyanurate group, a ureido group, a mercapto group, a sulfide group, or an isocyanate group, and an alkoxy group. With regard to details of the silane coupling agent, reference can be made to the description in paragraph Nos. 0467 to 0476 of JP2017-126044A, the contents of which are incorporated herein by reference. In a case where the photosensitive composition according to the embodiment of the present invention contains a silane coupling agent, the content of the silane coupling agent in the total solid content of the photosensitive composition is preferably 0.1% to 10% by mass. The lower limit is preferably 0.5% by mass or more and more preferably 1% by mass or more. The upper limit is preferably 8% by mass or less and more preferably 5% by mass or less. The photosensitive composition according to the embodiment of the present invention may include only one kind of silane coupling agent, or may include two or more kinds thereof. In a case where two or more kinds thereof are included, the total amount thereof is preferably within the above-described range.

<<Ultraviolet Absorber>>

The photosensitive composition according to the embodiment of the present invention can contain an ultraviolet absorber. As the ultraviolet absorber, a conjugated diene compound, an aminobutadiene compound, a methyldibenzoyl compound, a coumarin compound, a salicylate compound, a benzophenone compound, a benzotriazole compound, an acrylonitrile compound, a hydroxyphenyltriazine compound, or the like can be used. With regard to details thereof, reference can be made to the description in paragraph Nos. 0052 to 0072 of JP2012-208374A and paragraph Nos. 0317 to 0334 of JP2013-068814A, the contents of which are incorporated herein by reference. Examples of a commercially available product of the ultraviolet absorber include UV-503 (manufactured by Daito Chemical Co., Ltd.). In addition, as the benzotriazole compound, MYUA series manufactured by Miyoshi Oil & Fat Co., Ltd. (The Chemical Daily, Feb. 1, 2016) may be used. In a case where the photosensitive composition according to the embodiment of the present invention contains an ultraviolet absorber, the content of the ultraviolet absorber in the total solid content of the photosensitive composition is preferably 0.001% to 15% by mass. The lower limit is preferably 0.01% by mass or more and more preferably 0.1% by mass or more. The upper limit is preferably 10% by mass or less, more preferably 5% by mass or less, and still more preferably 3% by mass or less. In addition, the ultraviolet absorber may be used singly or in combination of two or more kinds thereof. In a case where two or more kinds thereof are used, it is preferable that the total amount thereof is within the above-described range.

<<Polymerization Inhibitor>>

The photosensitive composition according to the embodiment of the present invention can contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), and an N-nitrosophenylhydroxylamine salt (an ammonium salt, a cerous salt, or the like). In a case where the photosensitive composition according to the embodiment of the present invention contains a polymerization inhibitor, the content of the polymerization inhibitor in the total solid content of the photosensitive composition is preferably 0.001% to 5% by mass. The photosensitive composition according to the embodiment of the present invention may include only one kind of polymerization inhibitor, or may include two or more kinds thereof. In a case where two or more kinds thereof are included, the total amount thereof is preferably within the above-described range.

<<Other Additives>>

Additives such as a sensitizer, a co-sensitizer, a crosslinking agent, a curing accelerator, a filler, a thermosetting accelerator, a plasticizer, a diluent, an oil sensitizing agent, conductive particles, an antifoaming agent, a flame retardant, a leveling agent, a peeling accelerator, an antioxidant, a surface tension adjuster, and a chain transfer agent may be added to the photosensitive composition according to the embodiment of the present invention as desired. With regard to these components, reference can be made to the description in paragraph Nos. 0183 to 0228 of JP2012-003225A (paragraph Nos. 0237 to 0309 of the corresponding US2013/0034812A), paragraph Nos. 0101 and 0102, 0103 and 0104, and 0107 to 0109 of JP2008-250074A, and paragraph Nos. 0159 to 0184 of JP2013-195480A, the contents of which are incorporated herein by reference. In addition, as the antioxidant, for example, a phenol compound, a phosphorus-based compound (for example, the compounds described in paragraph No. 0042 of JP2011-090147A), a thioether compound, or the like can be used. Examples of a commercially available product thereof include ADEKA STAB series (AO-20, AO-30, AO-40, AO-50, AO-50F, AO-60, AO-60G, AO-80, AO-330, and the like) manufactured by ADEKA Corporation. In addition, as the antioxidant, polyfunctional hindered amine antioxidants described in WO2017/006600A and antioxidants described in WO2017/164024A can also be used.

In addition, as desired, the photosensitive composition according to the embodiment of the present invention may contain a potential antioxidant. Examples of the potential antioxidant include a compound in which a site functioning as an antioxidant is protected by a protecting group, and the protecting group is eliminated by heating the compound at 100° C. to 250° C. or heating the compound at 80° C. to 200° C. in the presence of an acid or basic catalyst and the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation).

The photosensitive composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 to 50 mPa×s and more preferably 0.5 to 20 mPa×s at 25° C. The viscosity can be measured, for example, with a temperature being adjusted to 25° C., using a viscometer RE85L (rotor: 1° 34′×R₂₄, measurement range of 0.6 to 1,200 mPa×s) manufactured by Toki Sangyo Co., Ltd.

A storage container for the photosensitive composition according to the embodiment of the present invention is not particularly limited, and a known storage container can be used. In addition, as the storage container, it is also preferable to use a multilayer bottle having an inner wall constituted with six layers from six kinds of resins or a bottle having a 7-layer structure from 6 kinds of resins for the purpose of suppressing incorporation of impurities into raw materials or photosensitive compositions. Examples of such a container include the containers described in JP2015-123351A.

<Method for Preparing Photosensitive Composition>

The photosensitive composition according to the embodiment of the present invention can be prepared by mixing the above-described components. In the preparation of the photosensitive composition, all the components may be dissolved or dispersed at the same time in a solvent to prepare the photosensitive composition, or two or more solutions or dispersion liquids in which the respective components are appropriately blended may be prepared in advance, and may be mixed with each other in a case of being used (coating) to prepare the photosensitive composition, as desired.

In addition, in a case where the photosensitive composition according to the embodiment of the present invention includes a pigment, in the preparation of the photosensitive composition, it is preferable to include a process for dispersing the pigment. In the process for dispersing the pigment, examples of a mechanical force which is used for dispersing the pigment include compression, pressing, impact, shear, and cavitation. Specific examples of a unit for performing these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be used. In addition, in the process for dispersing the pigment, a refining treatment of pigments in a salt milling step may be performed. With regard to the materials, the equipment, the treatment conditions, and the like used in the salt milling step, reference can be made to, for example, the description in JP2015-194521A and JP2012-046629A.

It is preferable that, in the preparation of the photosensitive composition, the photosensitive composition is filtered through a filter for the purpose of removing foreign matters, reducing defects, or the like. As the filter, any filters that have been used in the related art for filtration use and the like may be used without particular limitation. Examples of the filter include filters formed of materials including, for example, a fluorine resin such as polytetrafluoroethylene (PTFE), a polyamide-based resin such as nylon (for example, nylon-6 and nylon-6,6), and a polyolefin resin (including a polyolefin resin having a high-density or an ultrahigh molecular weight) such as polyethylene and polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be more reliably removed. With regard to the pore size value of the filter, reference can be made to a nominal value of filter manufacturers. As the filter, various filters provided by Nihon Pall Corporation (DFA4201NIEY and the like), Toyo Roshi Kaisha, Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. Here, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film and Method for Producing Film>

The film according to an embodiment of the present invention is a film obtained from the photosensitive composition according to the embodiment of the present invention. The film according to the embodiment of the present invention can be preferably used as a color pixel, a light-shielding film, a pixel of an infrared transmission filter layer, and the like.

Examples of the color pixel include a pixel having a hue selected from red, blue, green, cyan, magenta, and yellow.

Examples of the pixel of an infrared transmission filter layer include a pixel of a filter layer, which satisfies spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). In addition, the pixel of an infrared transmission filter layer is also preferably a pixel of a filter layer, which satisfies any one of the following spectral characteristics (1) to (4).

(1): pixel of a filter layer in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 80% or more).

(2): pixel of a filter layer in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): pixel of a filter layer in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): pixel of a filter layer in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

The light-shielding film can be used by being formed on various members (for example, an outer periphery of an infrared cut filter, an outer periphery of a solid-state imaging element, an outer periphery of a wafer level lens, a back surface of the solid-state imaging element, and the like) in an image display device and a sensor module. The reflectivity of the light-shielding film is preferably 10% or less, more preferably 8% or less, still more preferably 6% or less, and particularly preferably 4% or less. The reflectivity of the light-shielding film is a value obtained by entering light of 400 to 700 nm into the light-shielding film at an incidence angle of 5° and measuring the reflectivity with a spectroscope (UV4100, manufactured by Hitachi High-Tech Corporation).

The thickness of the film according to the embodiment of the present invention can be appropriately adjusted depending on applications and purposes. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

<Method for Forming Pattern>

The method for forming a pattern according to an embodiment of the present invention including:

a step of forming a photosensitive composition layer on a support using the photosensitive composition according to the embodiment of the present invention;

a step of irradiating the photosensitive composition layer with light to patternwise expose the photosensitive composition layer; and

a step of removing and developing the photosensitive composition layer of an unexposed area using a developer including an organic solvent.

Furthermore, a step of baking the photosensitive composition layer (pre-baking step) and a step of baking the developed pattern (post-baking step) may be provided after forming the photosensitive composition layer on the support and before exposing the photosensitive composition layer, as desired. Hereinafter, the respective steps will be described.

In the step of forming a photosensitive composition layer, the photosensitive composition layer is formed on a support using the photosensitive composition.

The support is not particularly limited, and can be appropriately selected depending on applications. Examples of the support include a glass substrate, a substrate for a solid-state imaging element, on which a solid-state imaging element (light-receiving element) is provided, and a silicon substrate. In addition, an undercoat layer may be provided on these substrates so as to improve adhesion to an upper layer, prevent the diffusion of substances, or planarize the surface.

As a method for applying the photosensitive composition onto the support, various coating methods such as slit coating, an ink jet method, spin coating, cast coating, roll coating, and a screen printing method can be used.

The photosensitive composition layer formed on the support may be dried (pre-baked). In a case of forming a pattern by a low-temperature process, the pre-baking may not be performed. In a case of performing the pre-baking, the pre-baking temperature is preferably 120° C. or lower, more preferably 110° C. or lower, and still more preferably 105° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the photosensitive composition layer is irradiated with light to patternwise expose the photosensitive composition layer (exposure step). For example, the photosensitive composition layer formed on the support can be subjected to patternwise exposure by performing exposure using an exposure device such as a stepper through a mask having a predetermined mask pattern. As a result, in the exposed area, by the action of acid generated from the photoacid generator, the solubility of the resin in the organic solvent can be decreased. Thus, the solubility of the photosensitive composition layer of the exposed area in the organic solvent can be decreased.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength 248 nm) and ArF-rays (wavelength 193 nm), and KrF-rays (wavelength 248 nm) are preferable.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50,000,000 W/m² or more, more preferably 100,000,000 W/m² or more, and still more preferably 200,000,000 W/m² or more. In addition, the upper limit of the maximum instantaneous illuminance is preferably 1,000,000,000 W/m² or less, more preferably 800,000,000 W/m² or less, and still more preferably 500,000,000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure dose) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, or substantially oxygen-free) or in a high-oxygen atmosphere having an oxygen concentration of more than 21% by volume (for example, 22% by volume, 30% by volume, or 50% by volume), in addition to an atmospheric air. In addition, the exposure illuminance can be appropriately set, and can be usually selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

Next, the photosensitive composition layer of an unexposed area is removed and developed using a developer including an organic solvent (development step). As a result, the photosensitive composition layer of the unexposed area is removed by the developer, and a pattern (negative tone pattern) which follows the shape of an opening of the mask is formed.

Examples of the organic solvent used in the developer include a ketone-based solvent, an ester-based solvent, an alcohol-based solvent, an amide-based solvent, an ether-based solvent, and a hydrocarbon-based solvent, and a ketone-based solvent, an ester-based solvent, or an ether-based solvent is preferable, a ketone-base solvent or an ester-based solvent is more preferable, and an ester-based solvent is still more preferable.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate (isoamyl acetate), amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate.

As the alcohol-based solvent, the amide-based solvent, the ether-based solvent, and the hydrocarbon-based solvent, solvents described in paragraphs 0715 to 0718 of US2016/0070167A can be used.

A plurality of the above-described solvents may be mixed with each other, or a solvent other than the above-described solvents or water may be mixed thereto. The moisture content of the developer is preferably less than 50% by mass, more preferably less than 20% by mass, still more preferably less than 10% by mass, and even more preferably less than 5% by mass, and it is particularly preferable that the developer substantially contains no water.

The solubility parameter (SP) value of the organic solvent used in the developer is preferably 14 to 24 MPa^{1/2}. The upper limit of the SP value of the organic solvent is preferably 22 MPa^{1/2} or less, more preferably 20 MPa^{1/2} or less, and still more preferably 18 MPa^{1/2} or less. The lower limit of the SP value of the organic solvent is preferably 15 MPa^{1/2} or more and more preferably 16 MPa^{1/2} or more. In addition, the boiling point of the organic solvent used in the developer is preferably 100° C. to 140° C.

In addition, the vapor pressure of the developer at 20° C. is preferably 5 kPa or less, still more preferably 3 kPa or less, and particularly preferably 2 kPa or less. In a case where the vapor pressure of the developer is 5 kPa or less, excellent developability is obtained.

In the present invention, as the organic solvent used in the developer, butyl acetate, 2-heptanone, propylene glycol monomethyl ether acetate, isopentyl acetate (isoamyl acetate), ethyl lactate, cyclohexanone, or isobutyl isobutyrate is preferable, and butyl acetate is more preferable.

The content of the organic solvent in the developer is preferably 50% to 100% by mass, more preferably 80% to 100% by mass, still more preferably 90% to 100% by mass, and particularly preferably 95% to 100% by mass with respect to the total amount of the developer. In addition, the content of butyl acetate in the developer is preferably 50% to 100% by mass, more preferably 80% to 100% by mass, still more preferably 90% to 100% by mass, and particularly preferably 95% to 100% by mass with respect to the total amount of the developer.

The developer can contain a surfactant, an antioxidant, a basic compound, a stabilizer, an antifoaming agent, and the like.

As a developing method, a method of dipping a substrate in a tank filled with the developer for a certain period of time (dip method), a method of heaping up the developer onto a surface of a substrate by surface tension and allowing to stand for a certain period of time (paddle method), a method of spraying the developer on a surface of a substrate (spray method), a method of continuously discharging the developer onto a substrate spinning at a constant speed while scanning a developer discharging nozzle (dynamic dispense method), and the like can be applied. The treatment time (developing time) is not particularly limited as long as the photosensitive composition layer of the unexposed area is sufficiently dissolved. For example, 10 to 300 seconds is preferable and 20 to 120 seconds is more preferable. The temperature of the developer is preferably 0° C. to 50° C. and more preferably 15° C. to 35° C.

In the method for forming a pattern according to the embodiment of the present invention, after the above-described development step, it is preferable to include a step of washing the pattern with a rinse liquid (rinse step).

The vapor pressure of the rinse liquid at 20° C. is preferably 0.05 to 5 kPa, more preferably 0.1 to 5 kPa, and still more preferably 0.12 to 3 kPa. In a case where the vapor pressure of the rinse liquid is within the above-described range, the temperature uniformity in the plane of the support is improved, and further, the swelling of the pattern after the development step, due to the permeation of the rinse liquid, can be suppressed.

The rinse liquid is not particularly limited as long as the pattern after the development step is not dissolved, and a solution including a general organic solvent can be used. Examples of the organic solvent used in the rinse liquid include a hydrocarbon-based solvent, a ketone-based solvent, an ester-based solvent, an alcohol-based solvent, an amide-based solvent, and an ether-based solvent.

The moisture content of the rinse liquid is preferably 10% by mass or less, more preferably 5% by mass or less, and still more preferably 3% by mass or less. In a case where the moisture content of the rinse liquid is 10% by mass or less, good developability can be obtained.

The rinse liquid can contain a surfactant, an antioxidant, a basic compound, a stabilizer, an antifoaming agent, and the like.

The method of washing the pattern with a rinse liquid is not particularly limited, and for example, a method of continuously discharging the rinsing solution on a support spinning at a constant speed (spin coating method), a method of dipping a support in a tank filled with the rinse liquid for a certain period of time (dip method), a method of spraying the rinse liquid on a surface of a support (spray method), and the like can be applied.

After the development step (in a case of performing the rinse step, after the rinse step), it is preferable to performing a heat treatment (post-baking) after performing drying. The heating temperature is, for example, preferably 100° C. to 240° C. and more preferably 200° C. to 240° C. The post-baking can be performed continuously or batchwise by using a heating unit such as a hot plate, a convection oven (hot-air circulating dryer), and a high-frequency heater so that the film after development satisfies the above-described conditions.

<Color Filter>

Next, the color filter according to an embodiment of the present invention will be described. The color filter according to the embodiment of the present invention includes the film according to the embodiment of the present invention. In the color filter according to the embodiment of the present invention, the film thickness of the film can be appropriately adjusted depending on the purpose. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more. The color filter according to the embodiment of the present invention can be used for a solid-state imaging element such as a charge coupled device (CCD) and a complementary metal-oxide semiconductor (CMOS), an image display device, or the like.

<Method for Producing Color Filter>

Next, a method for producing the color filter according to the embodiment of the present invention will be described. The method for producing the color filter according to the embodiment of the present invention includes the method for forming a pattern according to the embodiment of the present invention. In the method for producing the color filter according to the embodiment of the present invention, it is preferable that the method for forming a pattern according to the embodiment of the present invention is performed twice or more times.

In addition, in the method for producing the color filter according to the embodiment of the present invention, it is preferable to, after forming a first pixel using the method for forming a pattern according to the embodiment of the present invention, form a second pixel on an area in which the first pixel using the method for forming a pattern according to the embodiment of the present invention is removed. According to this aspect, it is possible to form a pixel having good rectangularity and little light leak. In a case of forming three or more types of pixels, it is preferable that the method for forming a pattern according to the embodiment of the present invention is repeatedly performed for each type of pixel to form a target pixel of the area in which each pixel is removed.

<Solid-State Imaging Element>

The solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. In addition, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which a film forming each color pixel is embedded in a space partitioned in a lattice form by a partition wall. The partition wall in this case preferably has a low refractive index for each color pixel. Examples of an imaging device having such a structure include the devices described in JP2012-227478A and JP2014-179577A. An imaging device including the solid-state imaging element according to the embodiment of the present invention can also be used as a vehicle camera or a monitoring camera, in addition to a digital camera or electronic equipment (mobile phones or the like) having an imaging function.

<Image Display Device>

The film according to the embodiment of the present invention can be used for an image display device such as a liquid crystal display device and an organic electroluminescence display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Preparation of Pigment Dispersion Liquid>

Raw materials shown in the following table were mixed and dispersed for 3 hours using a beads mill (a high-pressure disperser with a pressure reducing mechanism, NANO-3000-10 (manufactured by Nippon BEE Chemical Co., Ltd.)) in which zirconia beads having a diameter of 0.3 mm were used. As a result, a pigment dispersion liquid was prepared. The numerical values representing the blending amount shown below indicate parts by mass.

TABLE 1

| | | a1-1 | a1-2 | a2-1 | a2-2 |
|---|---|---|---|---|---|
| Coloring material | PG58 | 13.25 | 13.25 | | |
| | PG7 | 2.12 | 2.12 | | |
| | PY185 | 2.1 | 2.1 | | |
| | PY139 | 2.55 | 2.55 | 8.3 | 8.3 |
| | PR254 | | | 11.7 | 11.7 |
| Resin | b-1 | 4.84 | | 4.84 | |
| | cb-1 | | 4.84 | | 4.84 |
| Pigment Derivative | d-1 | 1.83 | 1.83 | 1.83 | 1.83 |
| Solvent | s-1 | 73.31 | 73.31 | 73.33 | 73.33 |

(Coloring Material)

PG58: C. I. Pigment Green 58

PG7: C. I. Pigment Green 7

PY185: C. I. Pigment Yellow 185

PY139: C. I. Pigment Yellow 139

PR254: C. I. Pigment Red 254

(Resin)

b-1: resin (resin having solubility which decreases in the organic solvent due to the action of acid) synthesized by the following method

32.62 g of propylene glycol monomethyl ether acetate (PGMEA) was put into a three-neck flask equipped with a nitrogen introduction pipe and a cooling pipe, and heated to 86° C. 16.65 g of benzyl methacrylate (BzMA), 19.19 g of tetrahydrofuran-2-yl-acrylate (THFAA), and 5.76 g of t-butyl methacrylate (t-BuMa) were added thereto. A solution in which 0.8082 g (1.30% by mole with respect to a monomer) of dimethyl-2,2′-azobis(2-methylpropionate) (V-601, manufactured by FUJIFILM Wako Pure Chemical Corporation) was dissolved in 32.62 g of PGMEA was added dropwise to the mixed solution over 2 hours. Thereafter, the reaction solution was stirred for 2 hours to complete the reaction. A white powdery matter obtained by reprecipitating the reaction solution in heptane is recovered by filtration to obtain a resin b-1. The weight-average molecular weight (Mw) of the resin b-1 was 30,000. The amount of components having Mw of 1,000 or less was 3% by mass.

cb-1: resin having the following structure (Mw=24,000; a numerical value added to the main chain represents a molar ratio, and a numerical value added to the side chain represents the number of repeating units)

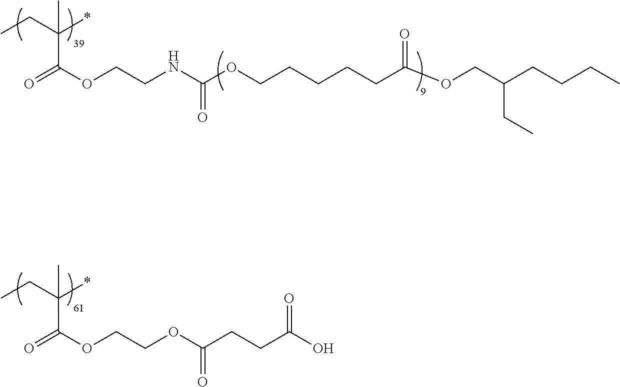

(Pigment Derivative)

d-1: compound having the following structure

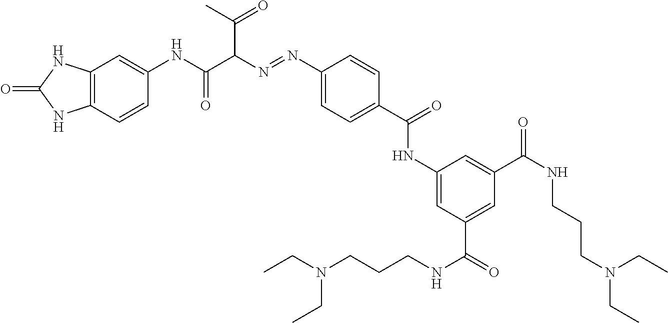 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

(Solvent) s-1: propylene glycol monomethyl ether acetate

<Preparation of Photosensitive Composition>

Raw materials shown in the following tables were mixed to prepare a photosensitive composition. The numerical values representing the blending amount shown in the following tables indicate parts by mass.

TABLE 2

| | | Example | Example | Example | Example | Example | Example | Example | Example | Comparative | Comparative |
|---|---|---|---|---|---|---|---|---|---|---|---|
| | | 1-1 | 1-2 | 1-3 | 1-4 | 1-5 | 1-6 | 1-7 | 1-8 | Example 1-1 | Example 1-2 |
| Pigment | a1-1 | 61.5 | 61.5 | 61.5 | 61.5 | 67.68 | 73.83 | 79.98 | 61.5 | | 61.5 |
| Dispersion | a1-2 | | | | | | | | | 61.5 | |
| Liquid | | | | | | | | | | | |
| Resin | b-1 | 2.14 | 3.16 | 4.7 | 7.26 | 5.6 | 3.95 | 2.31 | 3.8 | | 2.58 |
| | cb-1 | 5.12 | 4.1 | 2.56 | | | | | 2.23 | 7.26 | 5.53 |
| Photoacid | c-1 | 0.95 | 0.95 | 0.95 | 0.95 | 0.95 | 0.95 | 0.95 | 0.95 | 0.95 | |
| generator | | | | | | | | | | | |
| Acid | e-1 | | | | | | | | 1.23 | | |
| crosslinking | | | | | | | | | | | |
| agent | | | | | | | | | | | |
| Solvent | s-1 | 30.29 | 30.29 | 30.29 | 30.29 | 25.77 | 21.27 | 16.76 | 30.29 | 30.29 | 30.29 |

TABLE 3

| | | Example | Example | Example | Example | Example | Example | Example | Example | Comparative | Comparative |
|---|---|---|---|---|---|---|---|---|---|---|---|
| | | 2-1 | 2-2 | 2-3 | 2-4 | 2-5 | 2-6 | 2-7 | 2-8 | Example 2-1 | Example 2-2 |
| Pigment | a2-1 | 61.5 | 61.5 | 61.5 | 61.5 | 67.68 | 73.83 | 79.98 | 61.5 | | 61.5 |
| Dispersion | a2-2 | | | | | | | | | 61.5 | |
| Liquid | | | | | | | | | | | |
| Resin | b-1 | 2.14 | 3.16 | 4.7 | 7.26 | 5.6 | 3.95 | 2.31 | 3.8 | | 2.58 |
| | cb-1 | 5.12 | 4.1 | 2.56 | | | | | 2.23 | 7.26 | 5.53 |
| Photoacid | c-1 | 0.95 | 0.95 | 0.95 | 0.95 | 0.95 | 0.95 | 0.95 | 0.95 | 0.95 | |
| generator | | | | | | | | | | | |
| Acid | e-1 | | | | | | | | 1.23 | | |
| crosslinking | | | | | | | | | | | |
| agent | | | | | | | | | | | |
| Solvent | s-1 | 30.29 | 30.29 | 30.29 | 30.29 | 25.77 | 21.27 | 16.76 | 30.29 | 30.29 | 30.29 |

TABLE 4

| | | Example | Example | Example | Example |
|---|---|---|---|---|---|
| | | 3-1 | 3-2 | 3-3 | 3-4 |
| Pigment | a1-1 | 73.83 | 73.83 | 73.83 | 73.83 |
| Dispersion | | | | | |
| Liquid | | | | | |
| Resin | b-1 | 3.95 | 3.95 | 3.95 | 3.95 |
| Photoacid | c-2 | 0.95 | | | |
| generator | c-3 | | 0.95 | | |
| | c-4 | | | 0.95 | |
| | c-5 | | | | 0.95 |
| Solvent | s-1 | 21.27 | 21.27 | 21.27 | 21.27 |

(Photoacid Generator)

c-1 to c-5: compounds having the following structures (in the following structural formulae, Ts represents a tosyl group)

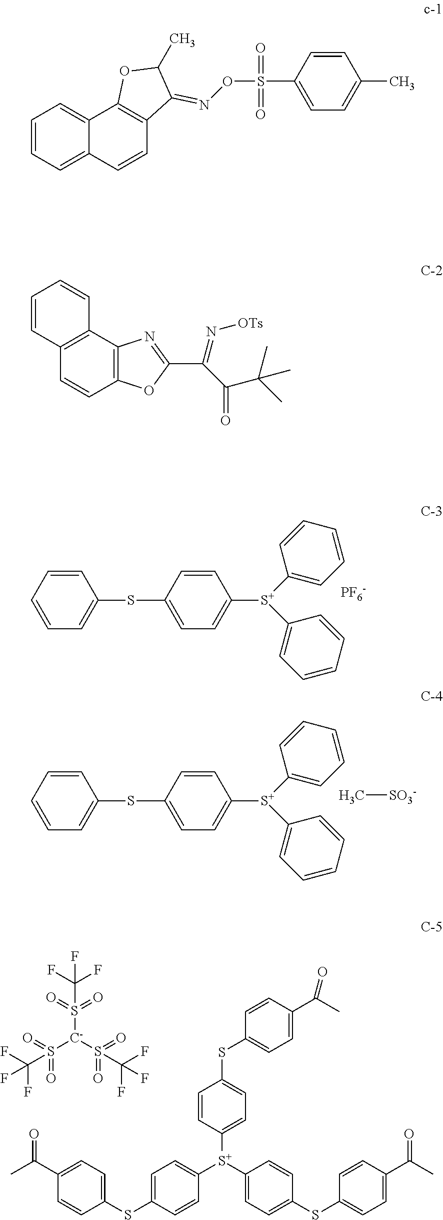

(Acid Crosslinking Agent)

e-1: EHPE 3150 (manufactured by Daicel Corporation)

<Evaluation>

Each photosensitive composition was placed and sealed in a glass container, stored at 5° C. for 10 months, and returned to room temperature, and the following evaluation 1 and evaluation 2 were performed to evaluate performance.

(Evaluation 1) Evaluation of Rectangularity of Pattern

Each photosensitive composition shown in the following tables was applied to an 8-inch (20.32 cm) silicon substrate according to a spin coating method, and subjected to a heat treatment (pre-baking) for 120 seconds using a hot plate at 100° C. to form a photosensitive composition layer having a thickness of 0.9 Next, using an i-ray stepper exposure device FPA-3000 i5+(manufactured by Canon Corporation), the photosensitive composition layer was exposed (exposure dose: 500 mJ/cm²) through a mask having a 1 μm×1 μm pattern. Next, using, as a developer, butyl acetate, 2-heptanone, propylene glycol monomethyl ether acetate (PGMEA), isoamyl acetate, ethyl lactate, cyclohexanone, isobutyl isobutylate, or an alkaline developer (0.3% by mass aqueous solution of tetramethylammonium hydroxide (TMAH)), the exposed photosensitive composition layer was subjected to shower development at 23° C. for 60 seconds. Thereafter, rinsing was performed by a spin shower using pure water. Next, using an oven at 200° C., a heat treatment (post-baking) was performed for 1 hour to obtain a pattern.

The width of the pattern formed on the silicon substrate and the length of a diagonal line of the pattern were observed from directly above the silicon substrate using a length measuring scanning electron microscope (SEM). Rectangularity was evaluated according to the following criteria. Rectangularity is better as a value of (Length of diagonal line of pattern/1.41)×100 is closer to 100.

6: value of (Length of diagonal line of pattern/1.41)×100 was more than 99 and 101 or less.

5: value of (Length of diagonal line of pattern/1.41)×100 was more than 98 and 99 or less, or more than 101 and 102 or less.

4: value of (Length of diagonal line of pattern/1.41)×100 was more than 97 and 98 or less, or more than 102 and 103 or less.

3: value of (Length of diagonal line of pattern/1.41)×100 was more than 96 and 97 or less, or more than 103 and 104 or less.

2: value of (Length of diagonal line of pattern/1.41)×100 was more than 95 and 96 or less, or more than 104 and 105 or less.

1: value of (Length of diagonal line of pattern/1.41)×100 was 95 or less, or more than 105.

(Evaluation 2) Evaluation of Light Leak (Crosstalk)

A photosensitive composition for forming a transparent pixel was applied to a glass substrate according to a spin coating method, and subjected to a heat treatment (pre-baking) for 120 seconds using a hot plate at 100° C. to form a photosensitive composition layer having a thickness of 0.9 As the photosensitive composition for forming a transparent pixel, the high refractive index material (titanium dioxide-containing curable composition B01) described in paragraph 0353 of JP2014-063125A was used.

Next, using an i-ray stepper exposure device FPA-3000 i5+(manufactured by Canon Corporation), the photosensitive composition layer was exposed (exposure dose: 500 mJ/cm²) through a mask having a 10 μm×10 μm pattern. Next, using an alkaline developer (0.3% by mass aqueous solution of tetramethylammonium hydroxide (TMAH)) as a developer, the exposed photosensitive composition layer was subjected to shower development at 23° C. for 60 seconds. Thereafter, rinsing was performed by a spin shower using pure water. Next, using an oven at 200° C., a heat treatment (post-baking) was performed for 1 hour to obtain a pattern (hereinafter, also referred to as a pattern 1) of a transparent pixel.

Next, the photosensitive composition shown in the following tables was applied to the glass substrate on which the pattern 1 was formed according to a spin coating method, and subjected to a heat treatment (pre-baking) for 120 seconds using a hot plate at 100° C. to form a photosensitive composition layer having a thickness of 0.9 μm. Next, using an i-ray stepper exposure device FPA-3000 i5+(manufactured by Canon Corporation), the photosensitive composition layer was exposed (exposure dose: 500 mJ/cm²) through a mask having a 10 μm×10 μm pattern. Next, using, as a developer, butyl acetate, 2-heptanone, propylene glycol monomethyl ether acetate (PGMEA), isoamyl acetate, ethyl lactate, cyclohexanone, isobutyl isobutylate, or an alkaline developer (0.3% by mass aqueous solution of tetramethylammonium hydroxide (TMAH)), the exposed photosensitive composition layer was subjected to shower development at 23° C. for 60 seconds. Thereafter, rinsing was performed by a spin shower using pure water. Next, using an oven at 200° C., a heat treatment (post-baking) was performed for 1 hour to obtain a pattern (hereinafter, also referred to as a pattern 2) formed of the photosensitive composition shown in the following tables in an area in which the pattern of a transparent pixel is removed.

The light amount at a wavelength max of the maximum transmittance in the light detected through the pattern 2 was defined as A, the light amount at the wavelength max detected through the pattern 1 was defined as B, and the light leak of pattern 2 was evaluated based on the following equation.

T=100×B/A

6: value of T was less than 2.

5: value of T was 2 or more and less than 4.

4: value of T was 4 or more and less than 6.

3: value of T was 6 or more and less than 10.

2: value of T was 10 or more and less than 12.

1: value of T was 12 or more.

Each evaluation is shown in the following tables. In the following tables, the numerical values shown in the column of “Content of resin (A) in all resins” is the content of the resin having solubility which decreases in the organic solvent due to the action of acid, in a total amount of resins included in the photosensitive composition.

TABLE 5

| | Photosensitive composition | | | | | | |
|---|---|---|---|---|---|---|---|
| | | Content of | | | | | |
| | | coloring | | Presence or | | | |
| | | material in | Content of resin | absence of | | | |
| | | total solid | (A) in total solid | acid | | | |
| | | content (% by | content (% by | crosslinking | Developer | Evaluation | Evaluation |
| | Type | mass) | mass) | agent | used | 1 | 2 |
| Test Example | Example 1-1 | 50 | 50 | Absence | Butyl acetate | 3 | 3 |
| 1-1 | | | | | | | |
| Test Example | Example 1-2 | 50 | 60 | Absence | Butyl acetate | 3 | 4 |
| 1-2 | | | | | | | |
| Test Example | Example 1-3 | 50 | 75 | Absence | Butyl acetate | 3 | 5 |
| 1-3 | | | | | | | |
| Test Example | Example 1-4 | 50 | 100 | Absence | Butyl acetate | 3 | 6 |
| 1-4 | | | | | | | |
| Test Example | Example 1-5 | 55 | 100 | Absence | Butyl acetate | 4 | 6 |
| 1-5 | | | | | | | |
| Test Example | Example 1-6 | 60 | 100 | Absence | Butyl acetate | 5 | 6 |
| 1-6 | | | | | | | |
| Test Example | Example 1-7 | 65 | 100 | Absence | Butyl acetate | 6 | 6 |
| 1-7 | | | | | | | |
| Test Example | Comparative | 50 | 0 | Absence | Butyl acetate | Film flow | Film flow |
| R1-1 | Example 1-1 | | | | | | |
| Test Example | Comparative | 50 | 50 | Absence | Butyl acetate | Film flow | Film flow |
| R1-2 | Example 1-2 | | | | | | |
| Test Example | Comparative | 50 | 0 | Absence | Alkaline | Film flow | Film flow |
| R1-3 | Example 1-1 | | | | developer | | |

TABLE 6

| | Photosensitive composition | | | | | | |
|---|---|---|---|---|---|---|---|
| | | Content of | | | | | |
| | | coloring | | Presence or | | | |
| | | material in | Content of resin | absence of | | | |
| | | total solid | (A) in total solid | acid | | | |
| | | content (% by | content (% by | crosslinking | Developer | Evaluation | Evaluation |
| | Type | mass) | mass) | agent | used | 1 | 2 |
| Test Example | Example 2-1 | 50 | 50 | Absence | Butyl acetate | 3 | 3 |
| 2-1 | | | | | | | |
| Test Example | Example 2-2 | 50 | 60 | Absence | Butyl acetate | 3 | 4 |
| 2-2 | | | | | | | |
| Test Example | Example 2-3 | 50 | 75 | Absence | Butyl acetate | 3 | 5 |
| 2-3 | | | | | | | |
| Test Example | Example 2-4 | 50 | 100 | Absence | Butyl acetate | 3 | 6 |
| 2-4 | | | | | | | |
| Test Example | Example 2-5 | 55 | 100 | Absence | Butyl acetate | 4 | 6 |
| 2-5 | | | | | | | |
| Test Example | Example 2-6 | 60 | 100 | Absence | Butyl acetate | 5 | 6 |
| 2-6 | | | | | | | |
| Test Example | Example 2-7 | 65 | 100 | Absence | Butyl acetate | 6 | 6 |
| 2-7 | | | | | | | |
| Test Example | Comparative | 50 | 0 | Absence | Butyl acetate | Film flow | Film flow |
| R2-1 | Example 2-1 | | | | | | |
| Test Example | Comparative | 50 | 50 | Absence | Butyl acetate | Film flow | Film flow |
| R2-2 | Example 2-2 | | | | | | |
| Test Example | Comparative | 50 | 0 | Absence | Alkaline | Film flow | Film flow |
| R2-3 | Example 2-1 | | | | developer | | |

TABLE 7

| | Photosensitive composition | | | | | | |
|---|---|---|---|---|---|---|---|
| | | Content of | | | | | |
| | | coloring | | Presence or | | | |
| | | material in | Content of resin | absence of | | | |
| | | total solid | (A) in total solid | acid | | | |
| | | content (% by | content (% by | crosslinking | Developer | Evaluation | Evaluation |
| | Type | mass) | mass) | agent | used | 1 | 2 |
| Test Example | Example 1-3 | 50 | 75 | Absence | Butyl acetate | 3 | 5 |
| 3-1 | | | | | | | |
| Test Example | Example 1-8 | 50 | 75 | Presence | Butyl acetate | 4 | 5 |
| 3-2 | | | | | | | |
| Test Example | Example 2-3 | 50 | 75 | Absence | Butyl acetate | 3 | 5 |
| 3-3 | | | | | | | |
| Test Example | Example 2-8 | 50 | 75 | Presence | Butyl acetate | 4 | 5 |
| 3-4 | | | | | | | |

TABLE 8

| | Photosensitive composition | | | | | | |
|---|---|---|---|---|---|---|---|
| | | Content of | | | | | |
| | | coloring | | Presence or | | | |
| | | material in | Content of resin | absence of | | | |
| | | total solid | (A) in total solid | acid | | | |
| | | content (% by | content (% by | crosslinking | Developer | Evaluation | Evaluation |
| | Type | mass) | mass) | agent | used | 1 | 2 |
| Test Example | Example 3-1 | 60 | 100 | Absence | Butyl acetate | 5 | 6 |
| 4-1 | | | | | | | |
| Test Example | Example 3-2 | 60 | 100 | Absence | Butyl acetate | 5 | 6 |
| 4-2 | | | | | | | |
| Test Example | Example 3-3 | 60 | 100 | Absence | Butyl acetate | 5 | 6 |
| 4-3 | | | | | | | |
| Test Example | Example 3-4 | 60 | 100 | Absence | Butyl acetate | 5 | 6 |
| 4-4 | | | | | | | |

TABLE 9

| | Photosensitive composition | | | | | | |
|---|---|---|---|---|---|---|---|
| | | Content of | | | | | |
| | | coloring | | Presence or | | | |
| | | material in | Content of resin | absence of | | | |
| | | total solid | (A) in total solid | acid | | | |
| | | content (% by | content (% by | crosslinking | Developer | Evaluation | Evaluation |
| | Type | mass) | mass) | agent | used | 1 | 2 |
| Test Example | Example | 60 | 100 | Absence | 2-heptanone | 5 | 6 |
| 5-1 | 1-6 | | | | | | |
| Test Example | Example | 60 | 100 | Absence | PGMEA | 5 | 6 |
| 5-2 | 1-6 | | | | | | |
| Test Example | Example | 60 | 100 | Absence | Isoamyl | 5 | 6 |
| 5-3 | 1-6 | | | | acetate | | |
| Test Example | Example | 60 | 100 | Absence | Ethyl lactate | 5 | 6 |
| 5-4 | 1-6 | | | | | | |
| Test Example | Example | 60 | 100 | Absence | Cyclohexanone | 5 | 6 |
| 5-5 | 1-6 | | | | | | |
| Test Example | Example | 60 | 100 | Absence | Isobutyl | 5 | 6 |
| 5-6 | 1-6 | | | | isobutylate | | |

As shown in the above tables, in each test example in which a negative tone pattern was formed, with a developer including an organic solvent, using a photosensitive composition of each example including a coloring material, a resin having solubility which decreases in the organic solvent due to the action of acid, and a photoacid generator, a pattern in which the rectangularity (evaluation 1) and light leak (evaluation 2) were suppressed could be formed.

In Test Examples R₁-1 to R₁-3 and Test Examples R₂-1 to R₂-3, since the pattern could not be formed, the rectangularity (evaluation 1) and light leak (evaluation 2) could not be evaluated.

### Test Example 6

A photosensitive composition for forming a green pixel was applied to an 8-inch (20.32 cm) glass substrate according to a spin coating method, and subjected to a heat treatment (pre-baking) for 120 seconds using a hot plate at 100° C. to form a photosensitive composition layer having a thickness of 0.9 μm. Next, using an i-ray stepper exposure device FPA-3000 i5+(manufactured by Canon Corporation), the photosensitive composition layer was exposed (exposure dose: 500 mJ/cm²) through a mask having a 3 μm×3 μm pattern. Next, using butyl acetate as a developer, the exposed photosensitive composition layer was subjected to shower development at 23° C. for 60 seconds. Thereafter, rinsing was performed by a spin shower using pure water. Next, using an oven at 200° C., a heat treatment (post-baking) was performed for 1 hour to form a pattern of a green pixel.

Next, a photosensitive composition for forming a red pixel was applied to the glass substrate on which the pattern of a green pixel was formed according to a spin coating method, and subjected to a heat treatment (pre-baking) for 120 seconds using a hot plate at 100° C. to form a photosensitive composition layer having a thickness of 0.9 μm. Next, using an i-ray stepper exposure device FPA-3000 i5+(manufactured by Canon Corporation), the photosensitive composition layer was exposed (exposure dose: 500 mJ/cm²) through a mask having a 3 μm×3 μm pattern. Next, using butyl acetate as a developer, the exposed photosensitive composition layer was subjected to shower development at 23° C. for 60 seconds. Thereafter, rinsing was performed by a spin shower using pure water. Next, using an oven at 200° C., a heat treatment (post-baking) was performed for 1 hour to form a pattern of a red pixel in an area in which the pattern of a green pixel is removed.

In a case where rectangularity of each of the green pixel and the red pixel was evaluated according to Evaluation 1, any rectangularity of the green pixel and the red pixel was “6”.

In addition, in a case where the spectral diffraction of the green pixel and the red pixel was performed using a microspectroscope to measure the light leak (crosstalk) to an adjacent pixel and evaluated according to Evaluation 2, the evaluation was “6”.

In Test Example 6, the photosensitive composition of Example 1-6 was used as the photosensitive composition for forming a green pixel, and the photosensitive composition of Example 2-6 was used as the photosensitive composition for forming a red pixel.

What is claimed is:

1. A photosensitive composition used for forming a negative tone pattern by development with a developer including an organic solvent, the photosensitive composition comprising:
a coloring material;
a resin having solubility which decreases in the organic solvent due to an action of acid; and
a photoacid generator.

2. The photosensitive composition according to claim 1,
wherein a content of the coloring material in a total solid content of the photosensitive composition is 55% by mass or more.

3. The photosensitive composition according to claim 1,
wherein a content of the resin having solubility which decreases in the organic solvent due to an action of acid, in a total amount of resins included in the photosensitive composition is 40% by mass or more.

4. The photosensitive composition according to claim 1,
wherein a content of the resin having solubility which decreases in the organic solvent due to an action of acid, in a total solid content of the photosensitive composition is 10% to 60% by mass.

5. The photosensitive composition according to claim 1,
wherein the resin having solubility which decreases in the organic solvent due to an action of acid, includes a group decomposed by the action of acid to generate a polar group.

6. The photosensitive composition according to claim 1,
wherein the resin having solubility which decreases in the organic solvent due to an action of acid, has a structure in which a polar group is protected by a group to be decomposed and to be eliminated by the action of acid.

7. The photosensitive composition according to claim 6,
wherein the group to be decomposed and to be eliminated by the action of acid is a group represented by any one of Formulae (Y1) to (Y4),
—C(R³¹)(R³²)(R³³) Formula (Y1):
—C(═O)OC(R³¹)(R³²)(R³³) Formula (Y2):
—C(R³⁶)(R³⁷)(OR³⁸) Formula (Y3):
—C(Rn)(H)(Ar) Formula (Y4):
in Formulae (Y1) and (Y2), R³¹ to R³³ each independently represent an alkyl group, and two of R³¹ to R³³ may be bonded to each other to form a ring,
in Formula (Y3), R³⁶ and R³⁷ each independently represent a hydrogen atom, an alkyl group, or an aryl group, in which at least one of R³⁶ or R³⁷ is an alkyl group or an aryl group, R³⁸ represents an alkyl group or an aryl group, and R³⁶ or R³⁷, and R³⁸ may be bonded to each other to form a ring, and
in Formula (Y4), Ar represents an aromatic ring group, Rn represents an alkyl group or an aryl group, and Rn and Ar may be bonded to each other to form a ring.

8. The photosensitive composition according to claim 6,
wherein a formula weight of the group to be decomposed and to be eliminated by the action of acid is 170 or less.

9. The photosensitive composition according to claim 1, further comprising:
an acid crosslinking agent.

10. The photosensitive composition according to claim 1,
wherein a content of a photoradical polymerization initiator in a total solid content of the photosensitive composition is 4% by mass or less.

11. The photosensitive composition according to claim 1,
wherein a content of a radical polymerizable monomer in a total solid content of the photosensitive composition is 5% by mass or less.

12. A film obtained from the photosensitive composition according to claim 1.

13. A method for forming a pattern, the method comprising:
forming a photosensitive composition layer on a support using the photosensitive composition according to claim 1;
irradiating the photosensitive composition layer with light to patternwise expose the photosensitive composition layer; and
removing and developing the photosensitive composition layer of an unexposed area using a developer including an organic solvent.

14. A method for producing a color filter, the method comprising:
after forming a first pixel using the method for forming a pattern according to claim 13, forming a second pixel on an area where the first pixel using the method for forming a pattern according to claim 13 is removed.

15. A color filter comprising:
the film according to claim 12.

16. A solid-state imaging element comprising:
the film according to claim 12.

17. An image display device comprising:
the film according to claim 12.
